(19) United States
(12) Patent Application Publication
(10) Pub. No.: US 2025/0169305 A1
(43) Pub. Date: May 22, 2025

(54) ELECTROLUMINESCENT DISPLAY DEVICE AND METHOD OF MANUFACTURING THE SAME

(71) Applicant: LG Display Co., Ltd., Seoul (KR)

(72) Inventors: Choong-Hyo KIM, Paju-si (KR); Moon-Soo KIM, Paju-si (KR)

(73) Assignee: LG Display Co., Ltd., Seoul (KR)

(21) Appl. No.: 18/948,191

(22) Filed: Nov. 14, 2024

(30) Foreign Application Priority Data
Nov. 21, 2023 (KR) 10-2023-0162227

(51) Int. Cl. H10K 59/131; H10K 59/12; H10K 59/80; H10K 102/00

(52) U.S. Cl. CPC H10K 59/131; H10K 59/1201; H10K 59/80522; H10K 2102/351

(57) ABSTRACT

An electroluminescent display device includes a substrate provided with a sub-pixel including an emission area and a contact area; a light-emitting diode in the emission area and including a first electrode, a light-emitting layer, and a second electrode; a first auxiliary electrode in the contact area and connected to the second electrode; and an insulation layer between the first auxiliary electrode and the light-emitting diode and having a contact hole exposing the first auxiliary electrode, wherein the contact hole includes a portion extending in a first direction and a portion extending in a second direction, and an undercut structure where a bottom surface of the insulation layer is exposed is provided at at least one side of the contact hole, and wherein the light-emitting layer is cut off by the undercut structure, and the second electrode is in contact with the first auxiliary electrode under the undercut structure.

### CROSS-REFERENCE TO RELATED APPLICATION

The present application claims priority to Korean Patent Application No. 10-2023-0162227 filed in the Republic of Korea on Nov. 21, 2023, the entire contents of which are hereby expressly incorporated by reference into the present application.

### BACKGROUND

### Technical Field

The present disclosure relates to a display device, and more particularly, to an electroluminescent display device including a light-emitting diode and a method of manufacturing the same.

### Discussion of the Related Art

As one of the flat panel display devices, an electroluminescent display device has wide viewing angles, as compared with a liquid crystal display device, because it is self-luminous. The electroluminescent display device also has advantages of a thin thickness, light weight and low power consumption because a backlight unit is not necessary.

In addition, the electroluminescent display device is driven by low voltages of direct current (DC) and has a fast response time. Further, the electroluminescent display device is strong against the external impacts and is used in a wide range of temperatures because its components are solids. Also, the electroluminescent display device can be manufactured at low costs.

The electroluminescent display device can include a plurality of pixels, each of which has a plurality sub-pixels emitting light of different colors, and can display various color images by allowing the plurality of sub-pixels to selectively emit light. Each sub-pixel includes a light-emitting diode, and the light-emitting diode includes a first electrode, a light-emitting layer, and a second electrode.

Here, the first electrode is provided for each sub-pixel, and the second electrode is provided commonly for all sub-pixels. That is, the second electrode is provided to correspond to an entire display area, so that the second electrode is formed in a relatively large area.

The resistance of the second electrode increases depending on the position, causing a difference in resistance. Accordingly, there is a problem that the luminance of the electroluminescent display device is non-uniform due to the difference in resistance.

### SUMMARY

Accordingly, embodiments of the present disclosure are directed to an electroluminescent display device and a method of manufacturing the same that substantially obviate one or more of the problems due to limitations and disadvantages of the related art.

An aspect of the present disclosure is to provide an electroluminescent display device having uniform luminance.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, an electroluminescent display device comprises a substrate provided with a sub-pixel including an emission area and a contact area; a light-emitting diode provided in the emission area over the substrate and including a first electrode, a light-emitting layer, and a second electrode; a first auxiliary electrode provided in the contact area over the substrate and connected to the second electrode; and an insulation layer between the first auxiliary electrode and the light-emitting diode and having a contact hole exposing the first auxiliary electrode, wherein the contact hole includes a portion extending in a first direction and a portion extending in a second direction, and an undercut structure where a bottom surface of the insulation layer is exposed is provided at at least one side of the contact hole, and wherein the light-emitting layer is cut off by the undercut structure, and the second electrode is connected to the first auxiliary electrode under the undercut structure.

In another aspect, a method of manufacturing an electroluminescent display device comprises forming a first auxiliary electrode over a substrate; forming a first insulation layer having a first contact hole and a second insulation layer having a second contact hole over the first auxiliary electrode; and forming a light-emitting diode over the second insulation layer, the light-emitting diode including a first electrode, a light-emitting layer, and a second electrode, wherein forming the first insulation layer having the first contact hole and the second insulation layer having the second contact hole includes forming an undercut structure where a bottom surface of the second insulation layer is exposed at at least one side of the second contact hole, wherein each of the first and second contact holes includes a portion extending in a first direction and a portion extending in a second direction, and wherein the light-emitting layer is cut off by the undercut structure, and the second electrode is connected to the first auxiliary electrode under the undercut structure.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and which are incorporated in and constitute a part of this application, illustrate embodiments of the disclosure and together with the description serve to explain various principles of the disclosure. In the drawings:

FIG. 1 is an example of an equivalent circuit diagram of one sub-pixel SP of an electroluminescent display device according to an embodiment of the present disclosure;

FIG. 2 is a schematic plan view of an electroluminescent display device according to an embodiment of the present disclosure;

FIG. 3 is a cross-sectional view of the line I-I′ of FIG. 2;

FIG. 4 is a schematic plan view of another electroluminescent display device according to an embodiment of the present disclosure;

FIG. 5 is a cross-sectional view of the line II-II′ of FIG. 4;

FIG. 6 is a schematic plan view of a contact area of an electroluminescent display device according to a first embodiment of the present disclosure;

FIG. 7 is a cross-sectional view corresponding to the line IIIA-IIIA′ and the line IIIB-IIIB′ of FIG. 6;

FIGS. 8A to 8H are schematic cross-sectional views of a contact area in steps of manufacturing an electroluminescent display device according to the first embodiment of the present disclosure;

FIGS. 9A and 9B are schematic plan views of a contact area of an electroluminescent display device where misalignment occurs according to the first embodiment of the present disclosure;

FIG. 10 is a schematic plan view of a contact area of an electroluminescent display device according to a second embodiment of the present disclosure;

FIG. 11 is a cross-sectional view corresponding to the line IVA-IVA′ and the line IVB-IVB′ of FIG. 10;

FIGS. 12A to 12G are schematic cross-sectional views of a contact area in steps of manufacturing an electroluminescent display device according to the second embodiment of the present disclosure;

FIG. 13 is a schematic plan view of a contact area of an electroluminescent display device according to a third embodiment of the present disclosure;

FIG. 14 is a cross-sectional view corresponding to the line VA-VA′ and the line VB-VB′ of FIG. 13;

FIGS. 15A to 15H are schematic cross-sectional views of a contact area in steps of manufacturing an electroluminescent display device according to the third embodiment of the present disclosure;

FIG. 16 is a schematic plan view of a contact area of an electroluminescent display device according to a fourth embodiment of the present disclosure; and

FIG. 17 is a cross-sectional view corresponding to the line VIA-VIA′ and the line VIB-VIB′ of FIG. 16.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship.

Hereinafter, exemplary embodiments of the present disclosure will be described in detail with reference to accompanying drawings.

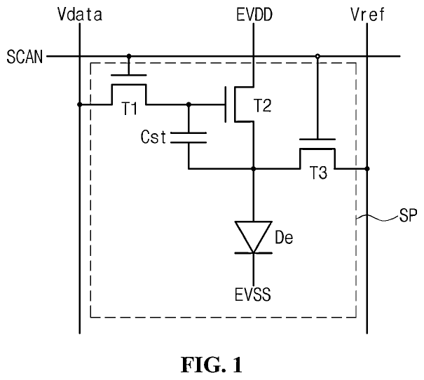

An electroluminescent display device according to embodiments of the present disclosure includes a plurality of pixels arranged in the form of a matrix (or any other form) in a display area, and each pixel includes a plurality of sub-pixels. Each sub-pixel has the same or substantially the same configuration as other sub-pixels. Now, one example of the configuration of such sub-pixel of the electroluminescent display device will be described with reference to FIG. 1, but other configurations are possible.

FIG. 1 is an example of an equivalent circuit diagram of one sub-pixel SP of an electroluminescent display device according to an embodiment of the present disclosure.

In FIG. 1, the sub-pixel SP of the electroluminescent display device according to the embodiment of the present disclosure can include first, second, and third transistors T1, T2, and T3, a storage capacitor Cst, and a light-emitting diode De. The first, second, and third transistors T1, T2, and T3 can be a switching transistor T1, a driving transistor T2, and a sensing transistor T3, respectively. The switching transistor T1, the driving transistor T2, and the sensing transistor T3 can be n-type transistors. However, the present disclosure is not limited thereto. Alternatively, the switching transistor T1, the driving transistor T2, and the sensing transistor T3 can be p-type transistors or other types of transistors.

A gate line supplying a scan signal (or gate signal) SCAN and a data line supplying a data signal Vdata can cross each other, and the switching transistor T1 can be disposed at a crossing point of the gate line and the data line. A gate of the switching transistor T1 can be connected to the gate line to receive the gate signal SCAN, and a drain of the switching transistor T1 can be connected to the data line to receive the data signal Vdata.

In addition, a gate of the driving transistor T2 can be connected to a source of the switching transistor T1 and a first capacitor electrode of the storage capacitor Cst. A drain of the driving transistor T2 can be connected to a high potential line supplying a high potential voltage EVDD, and a source of the driving transistor T2 can be connected to an anode of the light-emitting diode De, a second capacitor electrode of the storage capacitor Cst, and a source of the sensing transistor T3.

A gate of the sensing transistor T3 can be connected to the gate line, and a drain of the sensing transistor T3 can be connected to a reference line supplying a reference voltage Vref. Alternatively, the gate of the sensing transistor T3 can be connected to a separate sensing line.

Here, the source and drain locations of each of the transistors T1, T2, and T3 are not limited thereto, and the locations can be interchanged or varied.

Meanwhile, a cathode of the light-emitting diode De can be connected to a low potential line supplying a low potential voltage EVSS. Alternatively, the cathode of the light-emitting diode De can be connected to a ground voltage. As a variation, instead of the light-emitting diode De, another type of light-emitting element can be used.

During an emission period of one frame, the switching transistor T1 can be switched according to the gate signal SCAN transmitted through the gate line to thereby provide the gate of the driving transistor T2 with the data signal Vdata transmitted through the data line. The driving transistor T2 can be switched according to the data signal Vdata to thereby control a current of the light-emitting diode De. In this case, the storage capacitor Cst can maintain charges corresponding to the data signal Vdata for one frame. Accordingly, even if the switching transistor T1 is turned off, the storage capacitor Cst can allow the amount of the current flowing through the light-emitting diode De to be constant and the gray level shown by the light-emitting diode De to be maintained until a next frame.

In addition, one frame can further include a sensing period. During the sensing period, the sensing transistor T3 can be switched according to the gate signal SCAN transmitted through the gate line to thereby provide the source of the driving transistor T2 with the reference voltage Vref. The sensing transistor T3 can detect the voltage change of the source of the driving transistor T2 through the reference line and can calculate the threshold voltage Vth of the driving transistor T2 by comparing the amount of the voltage change with a determination range. Accordingly, by calculating the threshold voltage Vth in real time and compensating for the image data, it is possible to compensate for the change in the characteristics of the driving transistor T2 and prevent image degradation.

However, the configuration of the sub-pixel of the electroluminescent display device according to the embodiment of the present disclosure is not limited thereto. In some embodiments, the sensing transistor T3 can be omitted. In addition, the number and connection relationship of the transistors, the storage capacitor and/or the light-emitting diode can vary.

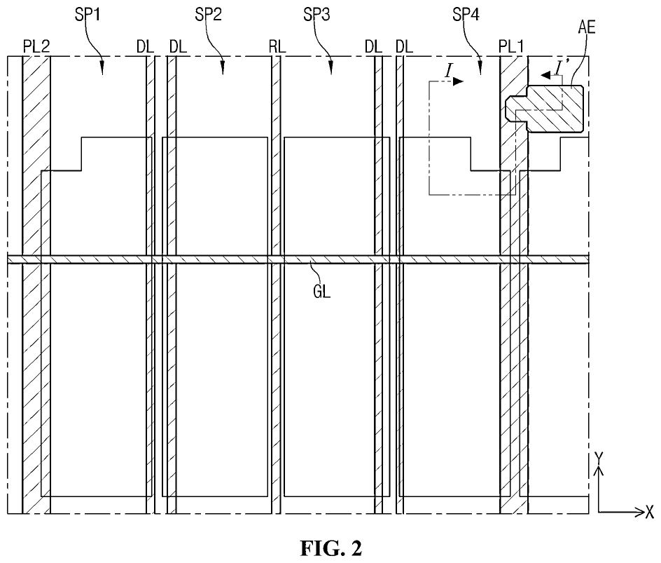

FIG. 2 is a schematic plan view of an electroluminescent display device according to an embodiment of the present disclosure and shows one sub-pixel. The electroluminescent display device according to an embodiment of the present disclosure can be a top emission type display device.

As shown in FIG. 2, in an electroluminescent display device according to an embodiment of the present disclosure, a gate line GL can extend in a first direction, which is an X direction. A plurality of data lines DL, a first power line PL1, a second power line PL2, and a reference line RL can extend in a second direction, which is a Y direction. The gate line GL can cross the data lines DL, the first power line PL1, the second power line PL2, and the reference line RL to thereby define a plurality of sub-pixels SP1, SP2, SP3, and SP4. Here, the first power line PL1 can be the low potential line supplying the low potential voltage EVSS of FIG. 1, and the second power line PL2 can be the high potential line supplying the high potential voltage EVDD of FIG. 1.

The gate line GL can pass through each sub-pixel SP1, SP2, SP3, and SP4. However, embodiments of the present disclosure are not limited thereto. Alternatively, the gate line GL can be disposed at a top or bottom portion of each sub-pixel SP1, SP2, SP3, and SP4.

One reference line RL can be disposed between the first and second power lines PL1 and PL2, and two data lines DL can be disposed between the first power line PL1 and the reference line RL and between the second power line PL2 and the reference line RL. Two data lines DL can be disposed adjacent to each other substantially at the center between the reference line RL and the first power line PL1 or second power line PL2.

Each sub-pixel SP1, SP2, SP3, and SP4 can have a substantially rectangular shape. However, embodiments of the present disclosure are not limited thereto, and each sub-pixel SP1, SP2, SP3, and SP4 can have other shapes.

As described above, one pixel can include the plurality of sub-pixels SP1, SP2, SP3, and SP4. For example, one pixel can include four sub-pixels, that is, first, second, third, and fourth sub-pixels SP1, SP2, SP3, and SP4. The first, second, third, and fourth sub-pixels SP1, SP2, SP3, and SP4 can be sequentially arranged along the first direction.

Here, the first sub-pixel SP1 can be a red sub-pixel, the second sub-pixel SP2 can be a green sub-pixel, the third sub-pixel SP3 can be a blue sub-pixel, and the fourth sub-pixel SP4 can be a white sub-pixel. However, embodiments of the present disclosure are not limited thereto. In other embodiments, the number of sub-pixels included in one pixel and/or the arrangement order of the red, green, blue, and white sub-pixels can be changed.

The first, second, third, and fourth sub-pixels SP1, SP2, SP3, and SP4 can have substantially the same area. However, embodiments of the present disclosure are not limited thereto. In other embodiments, the first, second, third, and fourth sub-pixels SP1, SP2, SP3, and SP4 can have different areas from each other.

Here, one power line PL1 or PL2, two data lines DL, or one reference line RL can be disposed substantially between adjacent sub-pixels SP1, SP2, SP3, and SP4. For example, two data lines DL can be disposed between the first and second sub-pixels SP1 and SP2 and between the third and fourth sub-pixels SP3 and SP4, one reference line RL can be disposed between the second and third sub-pixels SP2 and SP3, and one first power line PL1 can be disposed between the fourth sub-pixel SP4 and a first sub-pixel SP1 of a next pixel. In addition, two pixels adjacent to each other in the first direction can be symmetrical with respect to the first power line PL1 or second power line PL2. However, embodiments of the present disclosure are not limited thereto.

In each sub-pixel SP1, SP2, SP3, and SP4, the light-emitting diode De, the first, second, and third transistors T1, T2, and T3, and the storage capacitor Cst of FIG. 1 can be provided.

The light-emitting diode De can include a first electrode, a light-emitting layer, and a second electrode. The first electrode can be provided at each sub-pixel SP1, SP2, SP3, and SP4. The second electrode can be commonly provided over all sub-pixels SP1, SP2, SP3, and SP4.

Meanwhile, an auxiliary electrode AE can be provided to partially overlap the first power line PL1. The auxiliary electrode AE can be provided for each pixel and can be disposed to correspond to the fourth sub-pixel SP4.

The auxiliary electrode AE can be connected to the first power line PL1, and the second electrode of the light-emitting diode De can be connected to the auxiliary electrode AE. Accordingly, the second electrode of the light-emitting diode De can be electrically connected to the first power line PL1 through the auxiliary electrode AE. Therefore, the resistance of the second electrode can be reduced, and the luminance of the electroluminescent display device can be uniform.

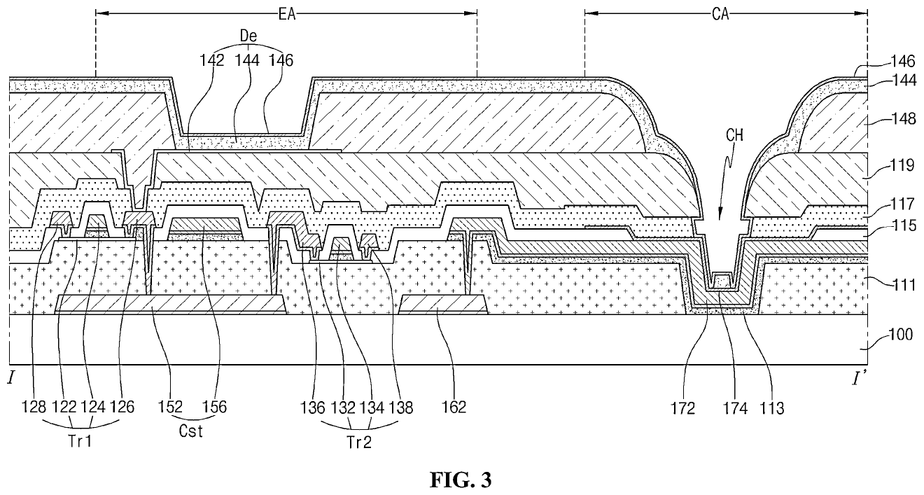

A cross-sectional configuration of the electroluminescent display device according to the embodiment of the present disclosure will be described with reference to FIG. 3.

FIG. 3 is a cross-sectional view of the line I-I′ of FIG. 2 and shows a cross-section of one sub-pixel.

In FIG. 3, a sub-pixel of the electroluminescent display device according to the embodiment of the present disclosure can include an emission area EA and a contact area CA provided on a substrate 100. A light-emitting diode De can be provided in the emission area EA, and an auxiliary electrode 172 and 174 can be provided in the contact area CA. The light-emitting diode De can include a first electrode 142, a light-emitting layer 144, and a second electrode 146. The second electrode 146 can also be provided in the contact area CA and be electrically connected to a power line 162 through the auxiliary electrode 172 and 174.

Specifically, a light-blocking layer 152 and the power line 162 can be provided on the substrate 100. The substrate 100 can be formed of a transparent insulating material and, for example, can be a glass substrate or a plastic substrate. Polyimide can be used for the plastic substrate, but embodiments are not limited thereto.

The light-blocking layer 152 can be disposed in the emission area EA, and a part of the light-blocking layer 152 can function as a first capacitor electrode. The power line 162 can be disposed substantially between the emission area EA and the contact area CA. Here, the power line 162 can correspond to the first power line PL1 of FIG. 2 and can be a low potential power line providing a low potential voltage.

The light-blocking layer 152 can be provided on the same layer and of the same material as the power line 162. The light-blocking layer 152 and the power line 162 can be formed of a conductive material such as metal. The light-blocking layer 152 and the power line 162 can be formed of one or more of: aluminum (Al), copper (Cu), molybdenum (Mo), titanium (Ti), chromium (Cr), nickel (Ni), tungsten (W), and an alloy thereof. For example, the light-blocking layer 152 and the power line 162 can have a double-layered structure including a lower layer of a molybdenum-titanium alloy (MoTi) and an upper layer of copper (Cu), and the upper layer can have a thicker thickness than the lower layer. However, embodiments of the present disclosure are not limited thereto. In other embodiments, the light-blocking layer 152 and the power line 162 can have a single-layered structure or a triple-layered structure.

A buffer layer 111 of an insulating material can be provided on the light-blocking layer 152 and the power line 162. The buffer layer 111 can be disposed over substantially an entire surface of the substrate 100. The buffer layer 111 can have a hole exposing the substrate 100 in the contact area CA. The buffer layer 111 can have a relatively thick thickness.

The buffer layer 111 can be formed of an inorganic insulating material, such as silicon oxide (SiO₂) or silicon nitride (SiNₓ), and can be formed as a single layer or multiple layers. Alternatively, the buffer layer 111 can be formed of an organic insulating material.

A first semiconductor layer 122 and a second semiconductor layer 132 can be patterned and provided on the buffer layer 111. The first semiconductor layer 122 and the second semiconductor layer 132 can be disposed to correspond to the emission area EA.

The first semiconductor layer 122 can overlap the light-blocking layer 152, and the second semiconductor layer 132 can be spaced apart from the light-blocking layer 152. The light-blocking layer 152 can block light incident on the first semiconductor layer 122, and reduce or prevent the first semiconductor layer 122 from deteriorating due to the light. However, embodiments of the present disclosure are not limited thereto. In other embodiments, both the first semiconductor layer 122 and the second semiconductor layer 132 can overlap the light-blocking layer 152.

The first semiconductor layer 122 and the second semiconductor layer 132 can be formed of an oxide semiconductor material.

Alternatively, the first semiconductor layer 122 and the second semiconductor layer 132 can be formed of polycrystalline silicon. In this case, both end portions of each of the first semiconductor layer 122 and the second semiconductor layer 132 can be doped with impurities.

A gate insulation layer 113 of an insulating material can be disposed on the buffer layer 111 provided with the first semiconductor layer 122 and the second semiconductor layer 132 thereon, and a first gate electrode 124, a second gate electrode 134, a second capacitor electrode 156, and a first auxiliary electrode 172 can be disposed on the gate insulation layer 113.

The gate insulation layer 113 can be patterned to have substantially the same shape as each of the first gate electrode 124, the second gate electrode 134, the second capacitor electrode 156, and the first auxiliary electrode 172. However, embodiments of the present disclosure are not limited thereto. In other embodiments, the gate insulation layer 113 can be disposed over substantially the entire surface of the substrate 100.

The gate insulation layer 113 can be formed of an inorganic insulating material, such as silicon oxide (SiO₂) or silicon nitride (SiNₓ). When the first semiconductor layer 122 and the second semiconductor layer 132 are made of an oxide semiconductor material, the gate insulation layer 113 can be formed of silicon oxide (SiO₂).

Alternatively, when the first semiconductor layer 122 and the second semiconductor layer 132 are made of polycrystalline silicon, the gate insulation layer 113 can be formed of silicon oxide (SiO₂) or silicon nitride (SiNₓ).

The first gate electrode 124, the second gate electrode 134, and the second capacitor electrode 156 can be disposed substantially in the emission area EA, and the first auxiliary electrode 172 can be disposed in the contact area CA.

In this case, the first gate electrode 124 can be disposed to correspond to a center of the first semiconductor layer 122, and the second gate electrode 134 can be disposed to correspond to a center of the second semiconductor layer 132. Accordingly, the first gate electrode 124 can overlap the light-blocking layer 152, and the second gate electrode 134 can be spaced part from the light-blocking layer 152. Alternatively, when the second semiconductor layer 132 overlaps the light-blocking layer 152, the second gate electrode 134 can overlap the light-blocking layer 152.

In addition, the second capacitor electrode 156 can overlap the light-blocking layer 152. The light-blocking layer 152 and the second capacitor electrode 156 overlapping each other can constitute a storage capacitor Cst with the buffer layer 111 and the gate insulation layer 113 interposed therebetween as a dielectric.

Meanwhile, the first auxiliary electrode 172 can overlap the power line 162 and be in contact with the power line 162 through a contact hole provided in the gate insulation layer 113 and the buffer layer 111.

Further, the gate insulation layer 113 under the first auxiliary electrode 172 can be in contact with the substrate 100 through the hole of the buffer layer 111.

The first gate electrode 124, the second gate electrode 134, the second capacitor electrode 156, and the first auxiliary electrode 172 can be formed of a conductive material such as metal. The first gate electrode 124, the second gate electrode 134, the second capacitor electrode 156, and the first auxiliary electrode 172 can be formed of one or more of: aluminum (Al), copper (Cu), molybdenum (Mo), titanium (Ti), chromium (Cr), nickel (Ni), tungsten (W), and an alloy thereof. For example, the first gate electrode 124, the second gate electrode 134, the second capacitor electrode 156, and the first auxiliary electrode 172 can have a double-layered structure, including a lower layer of a molybdenum-titanium alloy (MoTi) and an upper layer of copper (Cu), and the upper layer can be thicker than the lower layer. However, embodiments of the present disclosure are not limited thereto. In other embodiments, the first gate electrode 124, the second gate electrode 134, the second capacitor electrode 156, and the first auxiliary electrode 172 can have a single-layered structure or a triple-layered structure.

A first passivation layer 115 of an insulating material can be provided on the first gate electrode 124, the second gate electrode 134, the second capacitor electrode 156, and the first auxiliary electrode 172. The first passivation layer 115 can be disposed over substantially the entire surface of the substrate 100. The first passivation layer 115 can be an interlayer insulation layer and can be formed of an inorganic insulating material, such as silicon oxide (SiO₂) or silicon nitride (SiNₓ).

The first passivation layer 115 can have a contact hole exposing the first auxiliary electrode 172 in the contact area CA.

First source and first drain electrodes 126 and 128 and second source and second drain electrodes 136 and 138 can be disposed on the first passivation layer 115. The first source and first drain electrodes 126 and 128 and the second source and second drain electrodes 136 and 138 can be formed of a conductive material such as metal. The first source and first drain electrodes 126 and 128 and the second source and second drain electrodes 136 and 138 can be formed of one or more of: aluminum (Al), copper (Cu), molybdenum (Mo), titanium (Ti), chromium (Cr), nickel (Ni), tungsten (W), and an alloy thereof. For example, the first source and first drain electrodes 126 and 128 and the second source and second drain electrodes 136 and 138 can have a double-layered structure, including a lower layer of a molybdenum-titanium alloy (MoTi) and an upper layer of copper (Cu), and the upper layer can be thicker than the lower layer. However, embodiments of the present disclosure are not limited thereto. In other embodiments, the first source and first drain electrodes 126 and 128 and the second source and second drain electrodes 136 and 138 can have a single-layered structure or a triple-layered structure.

The first source electrode 126 and the first drain electrode 128 can be spaced apart from each other with the first gate electrode 124 positioned therebetween and can be in contact with the both end portions of the first semiconductor layer 122 through contact holes provided in the first passivation layer 115. In addition, the second source electrode 136 and the second drain electrode 138 can be spaced apart from each other with the second gate electrode 134 positioned therebetween and can be in contact with the both end portions of the second semiconductor layer 132 through contact holes provided in the first passivation layer 115.

The first semiconductor layer 122, the first gate electrode 124, the first source electrode 126, and the first drain electrode 128 can form a first thin film transistor Tr1. The second semiconductor layer 132, the second gate electrode 134, the second source electrode 136, and the second drain electrode 138 can form a second thin film transistor Tr2.

The first and second thin film transistors Tr1 and Tr2 can have a coplanar structure in which the gate electrode 124 and 134 and the source and drain electrodes 126, 128, 136, and 138 can be located at the same side with respect to the semiconductor layer 122 and 132, that is, disposed over the semiconductor layer 122 and 132.

Alternatively, the first and second thin film transistors Tr1 and Tr2 can have an inverted staggered structure in which the gate electrode and the source and drain electrodes can be located at different sides with respect to the semiconductor layer. That is, the gate electrode can be disposed under the semiconductor layer, and the source and drain electrodes can be disposed over the semiconductor layer. In this case, the semiconductor layer can be formed of oxide semiconductor or amorphous silicon.

The first thin film transistor Tr1 can be the driving transistor T2 of FIG. 1, and the second thin film transistor Tr2 can be the sensing transistor T3 of FIG. 1. In addition, at least one thin film transistor having substantially the same structure as the first and second thin film transistors Tr1 and Tr2, for example, the switching transistor T1 of FIG. 1, can be further provided on the substrate 100.

Meanwhile, the first source electrode 126 and the second source electrode 136 can be in contact with the light-blocking layer 152 through contact holes provided in the first passivation layer 115 and the buffer layer 111. Accordingly, the first and second thin film transistors Tr1 and Tr2 can be connected to the storage capacitor Cst.

Next, a second auxiliary electrode 174 can be disposed on the first passivation layer 115 in the contact area CA. The second auxiliary electrode 174 can be in contact with the first auxiliary electrode 172 through a contact hole provided in the first passivation layer 115. A thickness of the second auxiliary electrode 174 can be smaller than a thickness of the first auxiliary electrode 172.

The second auxiliary electrode 174 can be formed of a conductive material such as metal. For example, the second auxiliary electrode 174 can be formed of one or more of: molybdenum (Mo), titanium (Ti), chromium (Cr), nickel (Ni), tungsten (W), and an alloy thereof. Alternatively, the second auxiliary electrode 174 can be formed of a transparent conductive material. For example, the second auxiliary electrode 174 can be formed of indium tin oxide (ITO) or indium zinc oxide (IZO). The second auxiliary electrode 174 can have a single-layered structure.

Here, the first and second auxiliary electrodes 172 and 174 can correspond to the auxiliary electrode AE of FIG. 2, and the second auxiliary electrode 174 can be omitted.

A second passivation layer 117 of an insulating material can be provided on the first source and first drain electrodes 126 and 128, the second source and second drain electrodes 136 and 138, and the second auxiliary electrode 174. The second passivation layer 117 can be disposed over substantially the entire surface of the substrate 100. The second passivation layer 117 can be a protection layer. The second passivation layer 117 can be formed of an inorganic insulating material, such as silicon oxide (SiO₂) or silicon nitride (SiNₓ). A thickness of the second passivation layer 117 can be thicker than a thickness of the first passivation layer 115.

The second passivation layer 117 can have a contact hole exposing the second auxiliary electrode 174 in the contact area CA.

An overcoat layer 119 of an insulating material can be provided on the second passivation layer 117. The overcoat layer 119 can be disposed over substantially the entire surface of the substrate 100. The overcoat layer 119 and the second passivation layer 117 can have a contact hole exposing the first source electrode 126 in the emission area EA.

In addition, the overcoat layer 119 can have a contact hole CH corresponding to the first and second auxiliary electrodes 172 and 174 in the contact area CA, and an undercut structure where a bottom surface of the overcoat layer 119 is exposed can be provided to correspond to the contact hole CH.

The overcoat layer 119 can be a planarization layer. The overcoat layer 119 can be formed of an organic insulating material such as photosensitive acrylic polymer (photo acryl). The overcoat layer 119 can eliminate a step difference due to the layers thereunder and can have a substantially flat top surface. However, embodiments of the present disclosure are not limited thereto.

The first electrode 142 can be disposed on the overcoat layer 119 in the emission area EA and can be formed of a conductive material having relatively high work function. The first electrode 142 can be in contact with the first source electrode 126 through the contact hole provided in the overcoat layer 119 and the second passivation layer 117.

For example, the first electrode 142 can include a transparent conductive material such as indium tin oxide (ITO) or indium zinc oxide (IZO) or include titanium (Ti). However, embodiments of the present disclosure are not limited thereto.

Meanwhile, as described above, the electroluminescent display device according to the embodiment of the present disclosure can be a top emission type display device, in which light from the light-emitting layer 144 is output toward a direction opposite the substrate 100, that is, output to the outside through the second electrode 146. In this case, the first electrode 142 can have a multi-layered structure including a material with relatively high reflectance. For example, the first electrode 142 can be formed as a structure having relatively high reflectance such as a triple-layered structure of titanium, aluminum, and titanium (Ti/Al/Ti), a triple-layered structure of indium tin oxide, aluminum, and indium tin oxide (ITO/Al/ITO), a triple-layered structure of indium tin oxide, silver, and indium tin oxide (ITO/Ag/ITO), or a triple-layered structure of indium tin oxide, silver alloy, and indium tin oxide (ITO/Ag alloy/ITO). Here, the silver alloy can be an alloy of silver-palladium-copper (APC).

A bank 148 of an organic insulating material can be disposed on the first electrode 142. The bank 148 can overlap edges of the first electrode 142 and cover the edges of the first electrode 142. The bank 148 can expose a central portion of the first electrode 142.

In addition, the bank 148 can have a hole corresponding to the contact area CA.

Next, the light-emitting layer 144 can be provided on the first electrode 142 exposed by the bank 148. The light-emitting layer 144 can be disposed over substantially the entire surface of the substrate 100. Accordingly, in the emission area EA, the light-emitting layer 144 can be in contact with the first electrode 142 and also in contact with side and top surfaces of the bank 148.

Additionally, in the contact area CA, the light-emitting layer 144 can be in contact with top and side surfaces of the overcoat layer 119 and can be separated by the undercut structure. Accordingly, the light-emitting layer 144 can expose the second auxiliary electrode 174 corresponding to the undercut structure.

The light-emitting layer 144 can emit white light and can include at least one hole auxiliary layer, at least one light-emitting material layer, and at least one electron auxiliary layer constituting one light-emitting unit. The hole auxiliary layer can include at least one of a hole injection layer (HIL) and a hole transport layer (HTL). The electron auxiliary layer can include at least one of an electron injection layer (EIL) and an electron transport layer (ETL).

The light-emitting layer 144 can have a stack structure in which two or more light-emitting units emitting light of different colors are stacked, and a charge generation layer (CGL) can be provided between two light-emitting units.

The second electrode 146 of a conductive material with relatively low work function can be provided on the light-emitting layer 144. The second electrode 146 can be disposed over substantially the entire surface of the substrate 100.

The second electrode 146 can be formed of aluminum (Al), magnesium (Mg), silver (Ag), or an alloy thereof. In this case, the second electrode 146 can have a relatively thin thickness such that light from the light-emitting layer 144 can be transmitted therethrough. For example, the second electrode 146 can have a thickness of 5 nm to 10 nm, but embodiments of the present disclosure are not limited thereto.

Alternatively, the second electrode 146 can be formed of a transparent conductive material such as indium gallium oxide (IGO) or IZO.

The second electrode 146 can be in contact with a top surface of the light-emitting layer 144. In the contact area CA, the second electrode 146 may not be separated by the undercut structure and can be in contact with the second auxiliary electrode 174 exposed to correspond to the undercut structure. This will be described in detail later.

The first electrode 142, the light-emitting layer 144, and the second electrode 146 of the emission area EA can constitute the light-emitting diode De. Here, the first electrode 142 can serve as an anode, and the second electrode 146 can serve as a cathode. However, embodiments of the present disclosure are not limited thereto. In other embodiments, the first electrode 142 can serve as a cathode, and the second electrode 146 can serve as an anode.

Although not shown in the figure, a capping layer can be formed on the second electrode 146 over substantially the entire surface of the substrate 100. The capping layer can be formed of an insulating material having a relatively high refractive index. The wavelength of light traveling along the capping layer can be amplified by surface plasma resonance. Thus, the intensity of the peak can be increased, thereby improving the light efficiency in the top-emission type electroluminescent display device. For example, the capping layer can be formed as a single layer of an organic layer or an inorganic layer, or can be formed as organic/inorganic stacked layers.

In addition, although not shown in the figure, an encapsulation layer can be provided on the capping layer. The encapsulation layer can protect the light-emitting diode De from external moisture or oxygen. The encapsulation layer can include at least one inorganic layer and at least one organic layer.

As described above, the electroluminescent display device according to the embodiment of the present disclosure can be the top emission type display device, in which light from the light-emitting layer 144 of the light-emitting diode De is output toward a direction opposite the substrate 100, that is, output to the outside through the second electrode 146. The top emission type display device can have a wider emission area than a bottom emission type display device of the same size, which may improve luminance and reduce power consumption.

By the way, to transmit light, the second electrode 146 should be formed of a metal material to have a thin thickness or formed of a transparent conductive material. According to this, the resistance of the second electrode 146 can increase, and there is a difference of the resistance depending on locations. Therefore, in the embodiment of the present disclosure, to reduce the resistance of the second electrode 146, the second electrode 146 can be electrically connected to the power line 162 through the auxiliary electrode 172 and 174.

In this case, the light-emitting layer 144 can be disposed between the second electrode 146 and the auxiliary electrode 172 and 174. Since the light-emitting layer 144 has insulating properties and acts as a resistor, contact properties between the second electrode 146 and the auxiliary electrode 172 and 174 can be deteriorated.

Accordingly, in the embodiment of the present disclosure, by forming the undercut structure between the second electrode 146 and the first and second auxiliary electrodes 172 and 174, more particularly, between the light-emitting layer 144 and the first and second auxiliary electrodes 172 and 174 in the contact area CA, the light-emitting layer 144 can be separated to thereby expose the second auxiliary electrode 174, and the second electrode 146 can be in direct contact with the exposed second auxiliary electrode 174.

Therefore, the contact properties between the second electrode 146 and the first and second auxiliary electrodes 172 and 174 can be increased, and a difference in resistance of the second electrode 146 can be prevented, so that the luminance of the electroluminescent display device can be made uniform.

Meanwhile, an electroluminescent display device according to the embodiment of the present disclosure can further include a transparent area.

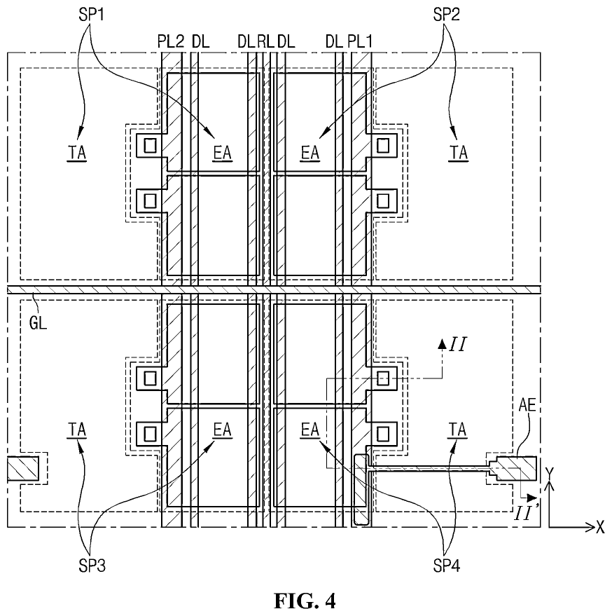

FIG. 4 is a schematic plan view of another electroluminescent display device according to an embodiment of the present disclosure and shows one sub-pixel. Another electroluminescent display device according to an embodiment of the present disclosure can be a transparent display device including an emission area and a transparent area.

As shown in FIG. 4, in another electroluminescent display device according to an embodiment of the present disclosure, a gate line GL can extend in a first direction, which is an X direction. A plurality of data lines DL, a first power line PL1, a second power line PL2, and a reference line RL can extend in a second direction, which is a Y direction. The gate line GL can cross the data lines DL, the first power line PL1, the second power line PL2, and the reference line RL to thereby define a plurality of sub-pixels SP1, SP2, SP3, and SP4. Here, the first power line PL1 can be the low potential line supplying the low potential voltage EVSS of FIG. 1, and the second power line PL2 can be the high potential line supplying the high potential voltage EVDD of FIG. 1.

The gate line GL can be disposed between adjacent sub-pixels SP1, SP2, SP3, and SP4 along the second direction. However, embodiments of the present disclosure are not limited thereto.

One reference line RL can be disposed between the first and second power lines PL1 and PL2, and two data lines DL can be disposed between the first power line PL1 and the reference line RL and between the second power line PL2 and the reference line RL.

Each sub-pixel SP1, SP2, SP3, and SP4 can have a substantially rectangular shape. However, embodiments of the present disclosure are not limited thereto, and each sub-pixel SP1, SP2, SP3, and SP4 can have other shapes.

As described above, one pixel can include the plurality of sub-pixels SP1, SP2, SP3, and SP4. For example, one pixel can include four sub-pixels, that is, first, second, third, and fourth sub-pixels SP1, SP2, SP3, and SP4. The first, second, third, and fourth sub-pixels SP1, SP2, SP3, and SP4 can be arranged in a pentile shape. That is, the first and second sub-pixels SP1 and SP2 can be disposed adjacent to each other in the first direction, the third and fourth sub-pixels SP3 and SP4 can be disposed adjacent to each other in the first direction, the first and third sub-pixels SP1 and SP3 can be disposed adjacent to each other in the second direction, and the second and fourth sub-pixels SP2 and SP4 can be disposed adjacent to each other in the second direction.

Here, the first sub-pixel SP1 can be a green sub-pixel, the second sub-pixel SP2 can be a white sub-pixel, the third sub-pixel SP3 can be a blue sub-pixel, and the fourth sub-pixel SP4 can be a red sub-pixel. However, embodiments of the present disclosure are not limited thereto. In other embodiments, the arrangement order of the red, green, blue, and white sub-pixels can be changed.

The first, second, third, and fourth sub-pixels SP1, SP2, SP3, and SP4 can have substantially the same area. However, embodiments of the present disclosure are not limited thereto. In other embodiments, at least one of the first, second, third, and fourth sub-pixels SP1, SP2, SP3, and SP4 can have a different area from others. Alternatively, the first, second, third, and fourth sub-pixels SP1, SP2, SP3, and SP4 can have different areas from each other.

Each of the first, second, third, and fourth sub-pixels SP1, SP2, SP3, and SP4 can include an emission area EA and a transparent area TA. The emission areas EA of the first, second, third, and fourth sub-pixels SP1, SP2, SP3, and SP4 can be disposed adjacent to each other. Accordingly, the emission areas EA of the first and second sub-pixels SP1 and SP2 can be disposed between the transparent areas TA of the first and second sub-pixels SP1 and SP2, and the emission areas EA of the third and fourth sub-pixels SP3 and SP4 can be disposed between the transparent areas TA of the third and fourth sub-pixels SP3 and SP4.

Here, the data line DL, the first power line PL1, and the second power line PL2 can be disposed to correspond to the emission area EA of the first, second, third, and fourth sub-pixels SP1, SP2, SP3, and SP4. The reference line RL can be disposed between the first and second sub-pixels SP1 and SP2 and between the third and fourth sub-pixels SP3 and SP4.

In each sub-pixel SP1, SP2, SP3, and SP4, the light-emitting diode De, the first, second, and third transistors T1, T2, and T3, and the storage capacitor Cst of FIG. 1 can be provided.

The light-emitting diode De can include a first electrode, a light-emitting layer, and a second electrode. The first electrode can be provided at each sub-pixel SP1, SP2, SP3, and SP4. The second electrode can be commonly provided over all sub-pixels SP1, SP2, SP3, and SP4. Here, the first electrode of each sub-pixel SP1, SP2, SP3, and SP4 can include two electrode patterns.

Meanwhile, an auxiliary electrode AE can be provided to partially overlap the first power line PL1. The auxiliary electrode AE can extend substantially in the first direction, and one end of the auxiliary electrode AE can overlap the first power line PL1. The auxiliary electrode AE can be provided for each pixel and can be disposed to correspond to the transparent area TA of the fourth sub-pixel SP4.

The auxiliary electrode AE can be connected to the first power line PL1, and the second electrode of the light-emitting diode De can be connected to the auxiliary electrode AE. Accordingly, the second electrode of the light-emitting diode De can be electrically connected to the first power line PL1 through the auxiliary electrode AE. Therefore, the resistance of the second electrode can be reduced, and the luminance of the electroluminescent display device can be uniform.

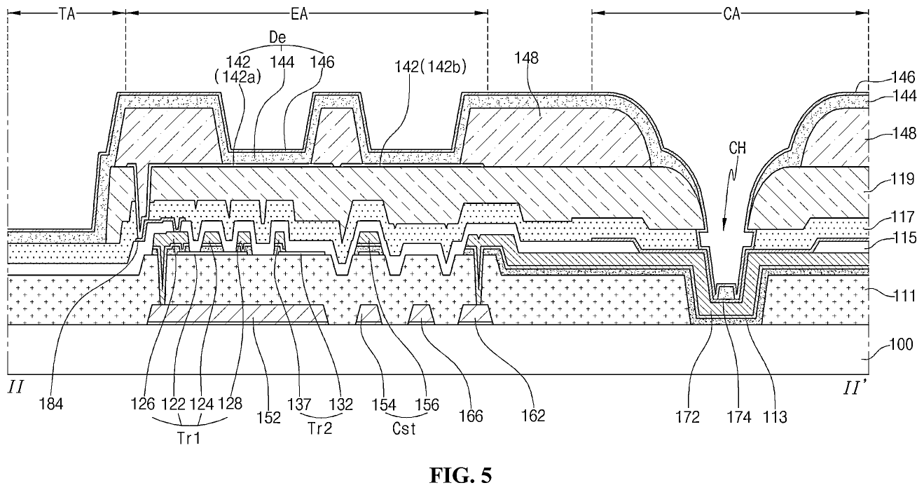

A cross-sectional configuration of another electroluminescent display device according to the embodiment of the present disclosure will be described with reference to FIG. 5.

FIG. 5 is a cross-sectional view of the line II-II′ of FIG. 4 and shows a cross-section of one sub-pixel. Another electroluminescent display device according to the embodiment of the present disclosure has substantially the same configuration as that of the previous embodiment of FIG. 3, except for a transparent area, a first electrode, and a connection electrode. The same parts as those of the previous embodiment are designated by the same reference signs, and explanation for the same parts may be shortened or omitted.

In FIG. 5, a sub-pixel of another electroluminescent display device according to the embodiment of the present disclosure can include an emission area EA, a transparent area TA, and a contact area CA provided on a substrate 100. A light-emitting diode De can be provided in the emission area EA, and an auxiliary electrode 172 and 174 can be provided in the contact area CA. The light-emitting diode De can include a first electrode 142, a light-emitting layer 144, and a second electrode 146, and the second electrode 146 can be electrically connected to a power line 162 through the auxiliary electrode 172 and 174.

Specifically, a light-blocking layer 152, the power line 162, a data line 166, and a first capacitor electrode 154 can be provided on the substrate 100.

The light-blocking layer 152, the power line 162, the data line 166, and the first capacitor electrode 154 can be disposed in the emission area EA. Here, the first capacitor electrode 154 can be connected to the light-blocking layer 152. In addition, the power line 162 can correspond to the first power line PL1 of FIG. 2 and can be a low potential power line providing a low potential voltage.

Meanwhile, according to the line II-II′ of FIG. 4, parts of the power line 162 and the data line 166 can also be disposed between the transparent area TA and the light-blocking layer 152, but can be omitted in FIG. 5 for convenience of illustration.

A buffer layer 111 of an insulating material can be provided on the light-blocking layer 152, the power line 162, the data line 166, and the first capacitor electrode 154. The buffer layer 111 can be disposed over substantially an entire surface of the substrate 100.

A first semiconductor layer 122 and a second semiconductor layer 132 can be patterned and provided on the buffer layer 111. The first semiconductor layer 122 and the second semiconductor layer 132 can be disposed to correspond to the emission area EA.

The first semiconductor layer 122 and the second semiconductor layer 132 can overlap the light-blocking layer 152. However, embodiments of the present disclosure are not limited thereto. In other embodiments, the first semiconductor layer 122 can overlap the light-blocking layer 152 and the second semiconductor layer 132 can be spaced apart from the light-blocking layer 152.

A gate insulation layer 113 of an insulating material can be disposed on the buffer layer 111 provided with the first semiconductor layer 122 and the second semiconductor layer 132 thereon. A first gate electrode 124, a first source electrode 126, a first drain electrode 128, a second source/drain electrode 137, a second capacitor electrode 156, and a first auxiliary electrode 172 can be disposed on the gate insulation layer 113. In addition, although not shown in the figure, a second gate electrode can be disposed on the gate insulation layer 113.

The gate insulation layer 113 can be patterned to have substantially the same shape as each of the first gate electrode 124, the first source electrode 126, the first drain electrode 128, the second source/drain electrode 137, the second capacitor electrode 156, and the first auxiliary electrode 172. However, embodiments of the present disclosure are not limited thereto. In other embodiments, the gate insulation layer 113 can be disposed over substantially the entire surface of the substrate 100.

The first gate electrode 124, the first source electrode 126, the first drain electrode 128, the second source/drain electrode 137, and the second capacitor electrode 156 can be disposed in the emission area EA, and the first auxiliary electrode 172 can be disposed in the contact area CA.

In this case, the first gate electrode 124 can correspond to a center of the first semiconductor layer 122 and can be disposed between the first source electrode 126 and the first drain electrode 128. The first source electrode 126 and the first drain electrode 128 can be disposed to correspond to the both end portions of the first semiconductor layer 122 and can be in contact with the both end portions of the first semiconductor layer 122 through contact holes provided in the gate insulation layer 113, respectively.

Although not shown in the figure, the second gate electrode can be disposed to correspond to a center of the second semiconductor layer 132. The second source/drain electrode 137 can be disposed to an end portion of the second semiconductor layer 132 and can be in contact with the end portion of the semiconductor layer 132 through a contact hole of the gate insulation layer 113.

In addition, the second capacitor electrode 156 can overlap the first capacitor electrode 154. The first capacitor electrode 154 and the second capacitor electrode 156 overlapping each other can constitute a storage capacitor Cst with the buffer layer 111 and the gate insulation layer 113 interposed therebetween as a dielectric.

A semiconductor pattern can be provided between the first capacitor electrode 154 and the second capacitor electrode 156. The semiconductor pattern can be formed of the same material and on the same layer as the first and second semiconductor layers 122 and 132. That is, the semiconductor pattern can overlap the first capacitor electrode 154 and the second capacitor electrode 156 and can be located between the buffer layer 111 and the gate insulation layer 113.

Meanwhile, the first auxiliary electrode 172 can overlap the power line 162 and be in contact with the power line 162 through a contact hole provided in the gate insulation layer 113 and buffer layer 111.

In addition, the gate insulation layer 113 under the first auxiliary electrode 172 can be in contact with the substrate 100 through the hole of the buffer layer 111.

The first semiconductor layer 122, the first gate electrode 124, the first source electrode 126, and the first drain electrode 128 can form a first thin film transistor Tr1. The second semiconductor layer 132, the second gate electrode, and the second source/second drain electrode 137 can form a second thin film transistor Tr2.

The first thin film transistor Tr1 can be the driving transistor T2 of FIG. 1, and the second thin film transistor Tr2 can be the switching transistor T1 or the sensing transistor T3 of FIG. 1. Meanwhile, at least one thin film transistor having substantially the same structure as the first and second thin film transistors Tr1 and Tr2 can be further provided on the substrate 100.

Here, the first source electrode 126 can be in contact with the light-blocking layer 152 through a contact hole provided in the gate insulation layer 113 and the buffer layer 111.

A first passivation layer 115 of an insulating material can be provided on the first gate electrode 124, the first source electrode 126, the first drain electrode 128, the second source/drain electrode 137, the second capacitor electrode 156, and the first auxiliary electrode 172. The first passivation layer 115 can be disposed over substantially the entire surface of the substrate 100. The first passivation layer 115 can be an interlayer insulation layer and can be formed of an inorganic insulating material, such as silicon oxide (SiO₂) or silicon nitride (SiNₓ).

The first passivation layer 115 can have a contact hole exposing the first source electrode 126 in the emission area EA and can have a contact hole exposing the first auxiliary electrode 172 in the contact area CA.

A connection electrode 184 and a second auxiliary electrode 174 can be provided on the first passivation layer 115. The connection electrode 184 can be disposed in the emission area EA, and the second auxiliary electrode 174 can be disposed in the contact area CA. In the emission area EA, the connection electrode 184 can be in contact with the first source electrode 126 through a contact hole provided in the first passivation layer 115. In the contact area CA, the second auxiliary electrode 174 can be in contact with the first auxiliary electrode 172 through a contact hole provided in the first passivation layer 115. A thickness of the second auxiliary electrode 174 can be smaller than a thickness of the first auxiliary electrode 172.

Here, the first and second auxiliary electrodes 172 and 174 can correspond to the auxiliary electrode AE of FIG. 4, and the second auxiliary electrode 174 can be omitted.

The connection electrode 184 and the second auxiliary electrode 174 can be formed of a conductive material such as metal. Alternatively, the connection electrode 184 and the second auxiliary electrode 174 can be formed of a transparent conductive material.

A second passivation layer 117 of an insulating material can be provided on the connection electrode 184 and the second auxiliary electrode 174. The second passivation layer 117 can be disposed over substantially the entire surface of the substrate 100. The second passivation layer 117 can be a protection layer. The second passivation layer 117 can be formed of an inorganic insulating material, such as silicon oxide (SiO₂) or silicon nitride (SiNₓ). A thickness of the second passivation layer 117 can be thicker than a thickness of the first passivation layer 115.

The second passivation layer 117 can have a contact hole exposing the second auxiliary electrode 174 in the contact area CA.

An overcoat layer 119 of an insulating material can be provided on the second passivation layer 117. The overcoat layer 119 can be disposed substantially in the emission area EA and can be removed in the transparent area TA to thereby expose the second passivation layer 117 in the transparent area TA. The overcoat layer 119 and the second passivation layer 117 can have a contact hole exposing the connection electrode 184 in the emission area EA. The contact hole exposing the connection electrode 184 can be spaced apart from the contact hole exposing the first source electrode 126.

In addition, the overcoat layer 119 can have a contact hole CH corresponding to the first and second auxiliary electrodes 172 and 174 in the contact area CA, and an undercut structure where a bottom surface of the overcoat layer 119 is exposed can be provided to correspond to the contact hole CH.

The first electrode 142 can be disposed on the overcoat layer 119 in the emission area EA and can be formed of a conductive material having relatively high work function.

For example, the first electrode 142 can include a transparent conductive material such as indium tin oxide (ITO) or indium zinc oxide (IZO) or include titanium (Ti). However, embodiments of the present disclosure are not limited thereto.

Meanwhile, as described above, the electroluminescent display device according to the embodiment of the present disclosure can be a top emission type display device, in which light from the light-emitting layer 144 is output toward a direction opposite the substrate 100, that is, output to the outside through the second electrode 146. In this case, the first electrode 142 can have a multi-layered structure including a material with relatively high reflectance.

The first electrode 142 can be divided into two patterns. That is, the first electrode 142 can include a first electrode pattern 142a and a second electrode pattern 142b. The first electrode pattern 142a can be in contact with a first end of the connection electrode 184 through the contact hole provided in the overcoat layer 119 and the second passivation layer 117. In addition, although not shown in the figure, the second electrode pattern 142b can be in contact with a second end of the connection electrode 184 through another contact hole provided in the overcoat layer 119 and the second passivation layer 117. Accordingly, the first electrode pattern 142a and the second electrode pattern 142b can be electrically connected to the first source electrode 126 through the connection electrode 184.

The first and second electrode patterns 142a and 142b can minimize deterioration in image quality by allowing partial light emission through repair when a defect occurs. Specifically, when the defect occurs in a portion corresponding to the first electrode pattern 142a during a manufacturing process or during operation, the first end of the connection electrode 184 connected to the first electrode pattern 142a can be cut off using a laser. Accordingly, while light is not emitted in the portion corresponding to the first electrode pattern 142a, light can be emitted in a portion corresponding to the second electrode pattern 142b, thereby preventing a defect in which an entire sub-pixel does not emit light.

A bank 148 of an organic insulating material can be disposed on the first electrode 142. The bank 148 can overlap edges of each of the first and second electrode patterns 142a and 142b and cover the edges of each of the first and second electrode patterns 142a and 142b. The bank 148 can expose a central portion of each of the first and second electrode patterns 142a and 142b.

The bank 148 may not be provided in the transparent area TA and the contact area CA. In this case, the bank 148 can have a hole corresponding to the contact area CA.

Next, the light-emitting layer 144 can be provided on the first electrode 142 exposed by the bank 148, that is, on the first and second electrode patterns 142a and 142b. The light-emitting layer 144 can be disposed over substantially the entire surface of the substrate 100. Accordingly, in the emission area EA, the light-emitting layer 144 can be in contact with the first and second electrode patterns 142a and 142b and also in contact with side and top surfaces of the bank 148.

Additionally, in the contact area CA, the light-emitting layer 144 can be in contact with top and side surfaces of the overcoat layer 119 and can be separated by the undercut structure. Accordingly, the light-emitting layer 144 can expose the second auxiliary electrode 174 corresponding to the undercut structure.

Meanwhile, the light-emitting layer 144 can also be provided in the transparent area TA. In the transparent area TA, the light-emitting layer 144 can be in contact with the top surface of the second passivation layer 117.

The light-emitting layer 144 can emit white light and can include at least one hole auxiliary layer, at least one light-emitting material layer, and at least one electron auxiliary layer constituting one light-emitting unit. The hole auxiliary layer can include at least one of a hole injection layer (HIL) and a hole transport layer (HTL). The electron auxiliary layer can include at least one of an electron injection layer (EIL) and an electron transport layer (ETL).

The light-emitting layer 144 can have a stack structure in which two or more light-emitting units emitting light of different colors are stacked, and a charge generation layer (CGL) can be provided between two light-emitting units.

The second electrode 146 of a conductive material with relatively low work function can be provided on the light-emitting layer 144. The second electrode 146 can be disposed over substantially the entire surface of the substrate 100.

The second electrode 146 can be formed of aluminum (Al), magnesium (Mg), silver (Ag), or an alloy thereof. In this case, the second electrode 146 can have a relatively thin thickness such that light from the light-emitting layer 144 can be transmitted therethrough. For example, the second electrode 146 can have a thickness of 5 nm to 10 nm, but embodiments of the present disclosure are not limited thereto.

Alternatively, the second electrode 146 can be formed of a transparent conductive material such as IGO or IZO.

The second electrode 146 can be in contact with a top surface of the light-emitting layer 144. In the contact area CA, the second electrode 146 may not be separated by the undercut structure and can be in contact with the second auxiliary electrode 174 exposed to correspond to the undercut structure. This will be described in detail later.

The first electrode 142, the light-emitting layer 144, and the second electrode 146 of the emission area EA can constitute the light-emitting diode De. Here, the first electrode 142 can serve as an anode, and the second electrode 146 can serve as a cathode. However, embodiments of the present disclosure are not limited thereto.

Meanwhile, although not shown in the figure, a capping layer and an encapsulation layer can be sequentially formed on the second electrode 146 and disposed over substantially the entire surface of the substrate 100.

As such, in another electroluminescent display device according to the embodiment of the present disclosure, each sub-pixel can include the emission area EA and the transparent area TA, so that the surrounding environment information such as backgrounds can be shown together through the transparent area TA while displaying a color image through the emission area EA.

In addition, by forming the undercut structure in the contact area CA, the light-emitting layer 144 can be separated, the second auxiliary electrode 174 can be exposed, and the second electrode 146 can be in direct contact with the exposed second auxiliary electrode 174, so that the contact properties between the second electrode 146 and the first and second auxiliary electrodes 172 and 174 can be increased. Accordingly, a difference in resistance of the second electrode 146 can be prevented, so that the luminance of the electroluminescent display device can be made uniform.

The configuration of the contact area according to embodiments of the present disclosure will be described in more detail with reference to accompanying drawings.

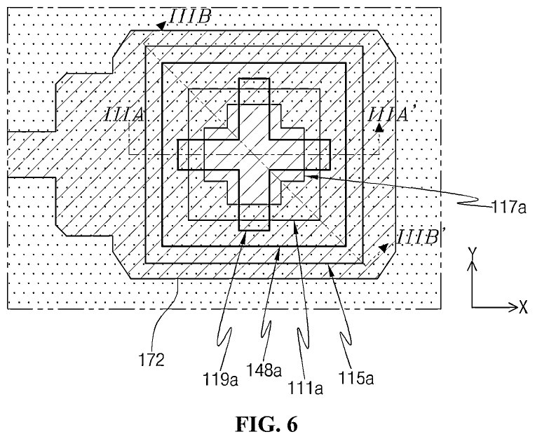

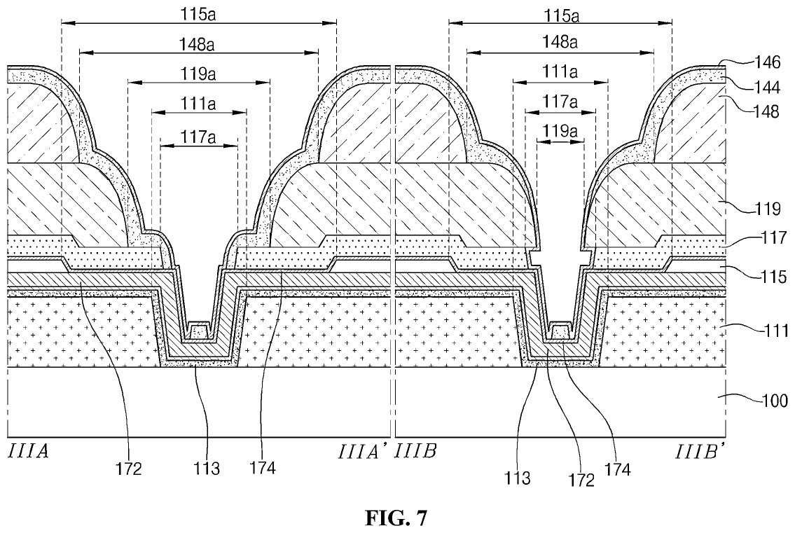

FIG. 6 is a schematic plan view of a contact area of an electroluminescent display device according to a first embodiment of the present disclosure, and FIG. 7 is a cross-sectional view corresponding to the line IIIA-IIIA′ and the line IIIB-IIIB′ of FIG. 6.

As shown in FIG. 6 and FIG. 7, in the electroluminescent display device according to the first embodiment of the present disclosure, the buffer layer 111 can have the relatively deep buffer hole 111a, the overcoat layer 119 can have a cross-shaped contact hole 119a in plan, and the second passivation layer 117, which is an insulation layer over the first and second auxiliary electrodes 172 and 174, can have a plurality of L-like shaped undercut structures in plan (i.e., in a plan view).

Specifically, the buffer layer 111 can be provided on the substrate 100. The buffer layer 111 can have a relatively thick thickness. For example, the thickness of the buffer layer 111 can be more than 5,000 Å and less than 7,000 Å.

The buffer layer 111 can have the buffer hole 111a exposing the substrate 100. A depth of the buffer hole 111a can be equal to the thickness of the buffer layer 111. A width of the buffer hole 111a can be smaller than the depth.

The gate insulation layer 113 and the first auxiliary electrode 172 can be sequentially disposed on the buffer layer 111. The gate insulation layer 113 can have the same shape as the first auxiliary electrode 172.

The gate insulation layer 113 and the first auxiliary electrode 172 can overlap the buffer hole 111a of the buffer layer 111. The gate insulation layer 113 and the first auxiliary electrode 172 can be formed along top and side surfaces of the buffer layer 111 corresponding to the buffer hole 111a. The gate insulation layer 113 can be in contact with the top and side surfaces of the buffer layer 111 and also be in contact with the substrate 100 in the buffer hole 111a. Accordingly, a relatively deep and narrow hole can be provided along the surface of the first auxiliary electrode 172 due to the buffer hole 111a.

The first passivation layer 115 can be provided on the first auxiliary electrode 172. The first passivation layer 115 can have a first contact hole 115a exposing a top surface of the first auxiliary electrode 172. The first contact hole 115a can have a larger area than the buffer hole 111a, and the buffer hole 111a can be disposed in the first contact hole 115a. The buffer hole 111a may not overlap the first passivation layer 115 and can be spaced apart from the first passivation layer 115 in plan.

The second auxiliary electrode 174 can be provided on the first passivation layer 115. The second auxiliary electrode 174 can be in contact with the first auxiliary electrode 172 exposed through the first contact hole 115a. The second auxiliary electrode 174 can have substantially the same shape and the same area as the first auxiliary electrode 172. The second auxiliary electrode 174 can overlap the buffer hole 111a and can be formed along the top and side surfaces of the buffer layer 111 corresponding to the buffer hole 111a. Accordingly, a relatively deep and narrow hole can be provided along the surface of the second auxiliary electrode 174 due to the buffer hole 111a.

The second auxiliary electrode 174 can be omitted.

The second passivation layer 117 can be provided on the second auxiliary electrode 174. The second passivation layer 117 can have a second contact hole 117a exposing the second auxiliary electrode 174.

The second contact hole 117a can include a portion extending in the first direction, which is the X direction, and a portion extending in the second direction, which is the Y direction, to thereby have a cross shape in plan and can be disposed in the first contact hole 115a. In addition, the second contact hole 117a can have a smaller area than the buffer hole 111a and can be disposed in the buffer hole 111a. The second contact hole 117a may not overlap the buffer layer 111 and the first passivation layer 115 and can be spaced apart from the buffer layer 111 and the first passivation layer 115 in plan.

The overcoat layer 119 can be provided on the second passivation layer 117. The overcoat layer 119 can have a substantially flat top surface and have a third contact hole 119a exposing the second passivation layer 117 and the second auxiliary electrode 174.

The third contact hole 119a can include a portion extending in the first direction and a portion extending in the second direction to thereby have a cross shape in plan. The third contact hole 119a can be disposed substantially in the buffer hole 111a, and each end of the third contact hole 119a can overlap the buffer layer 111.

In addition, the third contact hole 119a can have a smaller area than the first contact hole 115a and can be disposed in the first contact hole 115a. The third contact hole 119a may not overlap the first passivation layer 115 and can be spaced apart from the first passivation layer 115 in plan.

Meanwhile, a length of the cross-shaped third contact hole 119a can be greater than a length of the cross-shaped second contact hole 117a, and a width of the cross-shaped third contact hole 119a can be smaller than a width of the cross-shaped second contact hole 117a. Specifically, the length of the portion of the third contact hole 119a extending in the first direction can be greater than the length of the portion of the second contact hole 117a extending in the first direction, and the width of the portion of the third contact hole 119a extending in the first direction can be smaller than the width of the portion of the second contact hole 117a extending in the first direction. In addition, the length of the portion of the third contact hole 119a extending in the second direction can be greater than the length of the portion of the second contact hole 117a extending in the second direction, and the width of the portion of the third contact hole 119a extending in the second direction can be smaller than the width of the portion of the second contact hole 117a extending in the second direction.

Each end of the cross-shaped third contact hole 119a can overlap the second passivation layer 117, and others of the cross-shaped third contact hole 119a excluding the ends can be spaced apart from the second passivation layer 117.

Accordingly, the undercut structure where the bottom surface of the overcoat layer 119 is exposed can be provided between the third contact hole 119a and the second passivation layer 117 spaced apart from each other. The undercut structure can be provided to each corner of the cross-shaped third contact hole 119a. The cross-shaped third contact hole 119a can have an L-like side corresponding to each corner. For example, the cross-shaped third contact hole 119a can have four L-like sides. The undercut structure can be provided to correspond to each L-like side, thereby having an L-like shape in plan. Four undercut structures can be provided to correspond to the third contact hole 119a.

The bank 148 can be provided on the overcoat layer 119. The bank 148 can have a bank hole 148a corresponding to the second and third contact holes 117a and 119a. The bank hole 148a can have a larger area than the second and third contact holes 117a and 119a, and the second and third contact holes 117a and 119a can be disposed in the bank hole 148a. The top surfaces of the second passivation layer 117 and the overcoat layer 119 can be exposed through the bank hole 148a.

Further, the bank hole 148a can have a larger area than the buffer hole 111a and a smaller area than the first contact hole 115a. That is, the width and length of the bank hole 148a can be greater than the width and length of the buffer hole 111a and smaller than the width and length of the first contact hole 115a. The bank hole 148a can be disposed in the first contact hole 115a, and the buffer hole 111a can be disposed in the bank hole 148a. The bank hole 148a can be spaced apart from the first passivation layer 115.

The light-emitting layer 144 and the second electrode 146 can be sequentially provided on the bank 148. The light-emitting layer 144 and the second electrode 146 can be formed over substantially the entire surface of the substrate 100. The light-emitting layer 144 and the second electrode 146 can cover top and side surfaces of the bank 148 and also cover the top and side surfaces of the overcoat layer 119 exposed through the bank hole 148a. In addition, the light-emitting layer 144 and the second electrode 146 can cover the top and side surfaces of the second passivation layer 117 exposed through the second contact hole 119a. The light-emitting layer 144 can be in contact with the top and side surfaces of the bank 148, be in contact with the top and side surfaces of the overcoat layer 119, and be in contact with the top and side surfaces of the second passivation layer 117.

The light-emitting layer 144 can be formed through a thermal evaporation method with relatively low step coverage characteristics. Accordingly, at the side surface of the overcoat layer 119 corresponding to the undercut structure, the light-emitting layer 144 can have a thickness that decreases as it approaches or gets closer to the substrate 100 and then be cut off by the undercut structure. Therefore, the top surface of the second auxiliary electrode 174 corresponding to the undercut structure can be exposed.

In addition, the light-emitting layer 144 can be separated by the buffer hole 111a. That is, corresponding to the buffer hole 111a, the light-emitting layer 144 can be formed on the second auxiliary electrode 174 corresponding to the bottom of the relatively deep and narrow buffer hole 111a and may not be formed on the second auxiliary electrode 174 corresponding to the side wall of the buffer hole 111a. Accordingly, the second auxiliary electrode 174 corresponding to the side wall of the buffer hole 111a can be exposed.

On the other hand, the second electrode 146 can be formed through a sputtering method with relatively high step coverage characteristics. The second electrode 146 may not be cut off by the undercut structure. In addition, the second electrode 146 may not be separated by the buffer hole 111a and can be formed along the side wall and bottom of the buffer hole 111a.

Accordingly, the second electrode 146 can be in contact with the top surface of the second auxiliary electrode 174 exposed to correspond to the undercut structure and be in contact with the second auxiliary electrode 174 exposed at the side wall of the buffer hole 111a, thereby being electrically connected to the first auxiliary electrode 172 through the second auxiliary electrode 174.

As such, in the electroluminescent display device according to the first embodiment of the present disclosure, the third contact hole 119a of the overcoat layer 119 can be configured to have the cross shape in plan, the undercut structure can be provided to correspond to the third contact hole 119a, and the light-emitting layer 144 can be separated by the undercut structure, so that the second electrode 146 can be in direct contact with the second auxiliary electrode 174. Accordingly, the contact area between the second electrode 146 and the second auxiliary electrode 174 can increase to thereby improve the contact properties between the second electrode 146 and the second auxiliary electrode 174.

In this case, even if misalignment occurs between the upper layer and the lower layer during the manufacturing process, the undercut structure can be provided to correspond to the third contact hole 119a having the cross shape in plan, so that the second electrode 146 can be in contact with the second auxiliary electrode 174.

In addition, the buffer layer 111 can be configured to have the relatively thick thickness, thereby providing the relatively deep and narrow buffer hole 111a. The light-emitting layer 144 can be separated by the buffer hole 111a, so that the second electrode 146 can be in direct contact with the second auxiliary electrode 174. Accordingly, the contact area between the second electrode 146 and the second auxiliary electrode 174 can further increase. In this case, the thickness of the buffer layer 111 can be greater than the total thickness of the first and second passivation layers 115 and 117 and can be equal to or smaller than the thickness of the overcoat layer 119.

Meanwhile, it is shown that the buffer hole 111a, the bank hole 148a, and the first contact hole 115a have a square shape in plan and the second and third contact holes 117a and 119a have substantially the same length in the first direction and the second direction. However, embodiments of the present disclosure are not limited thereto. In other embodiments, the buffer hole 111a, the bank hole 148a, and the first contact hole 115a can have a rectangular shape in plan, and the second and third contact holes 117a and 119a can have different lengths in the first direction and the second direction.

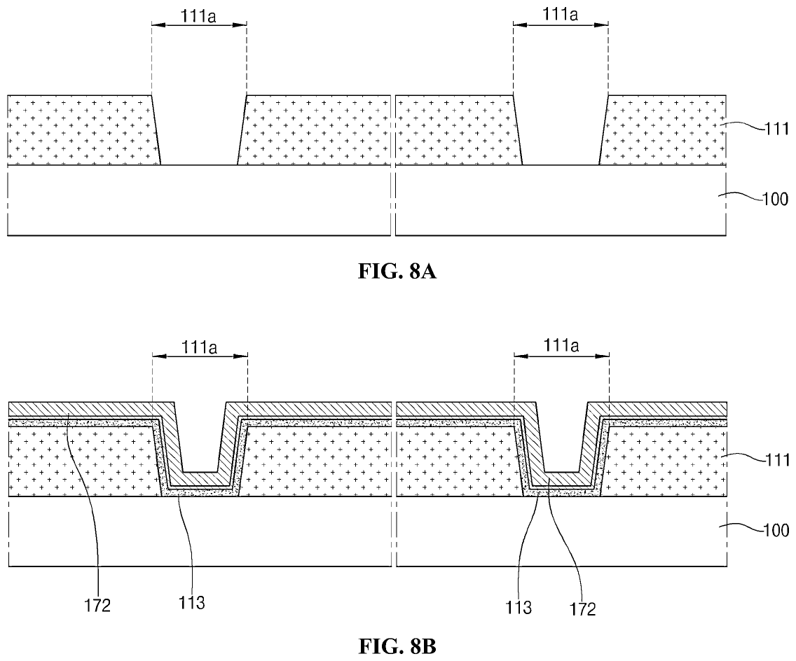

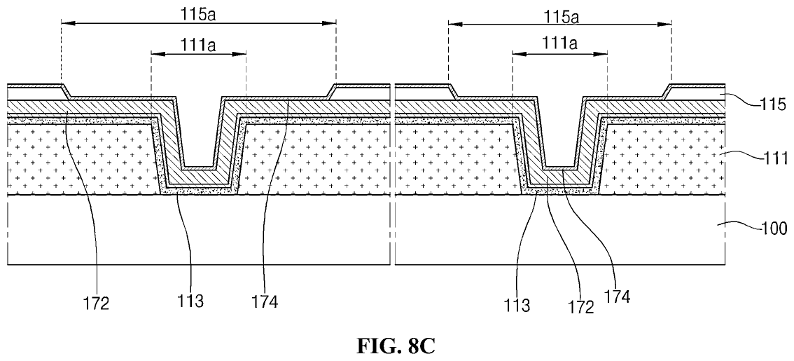

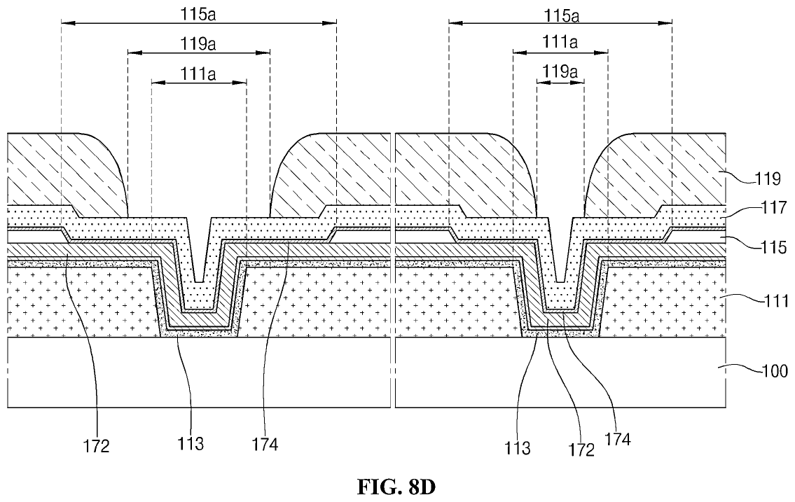

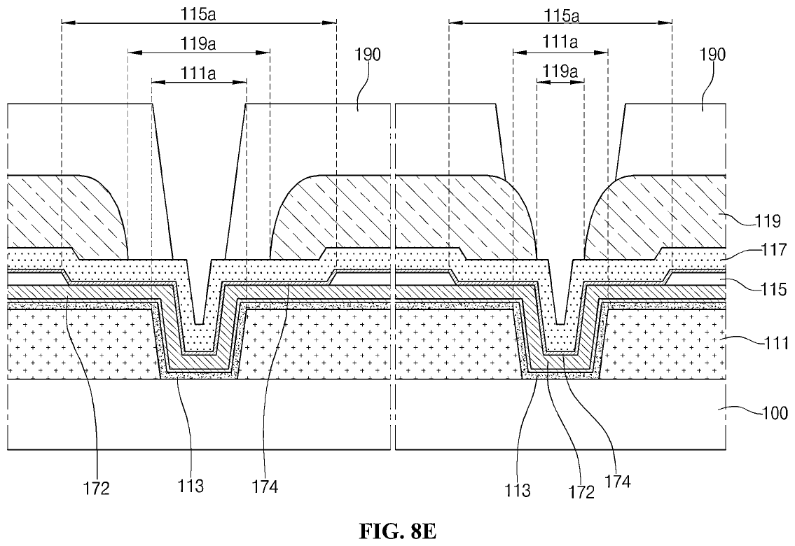

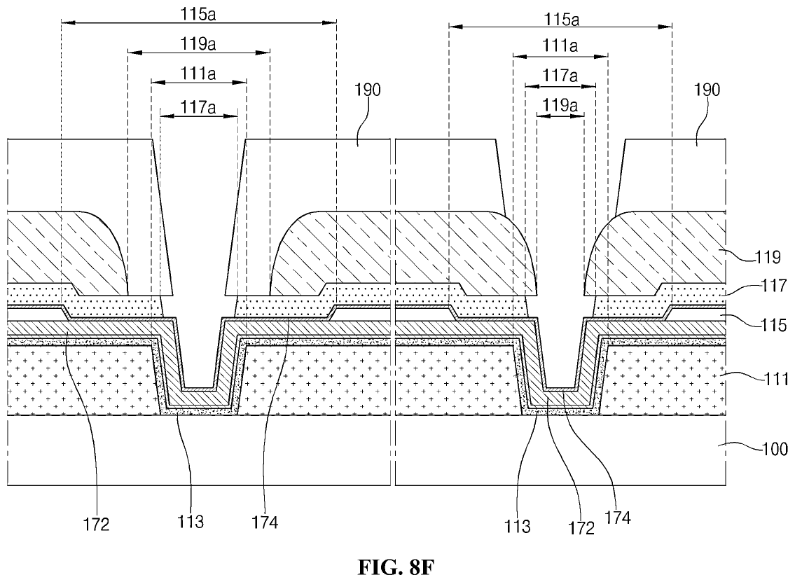

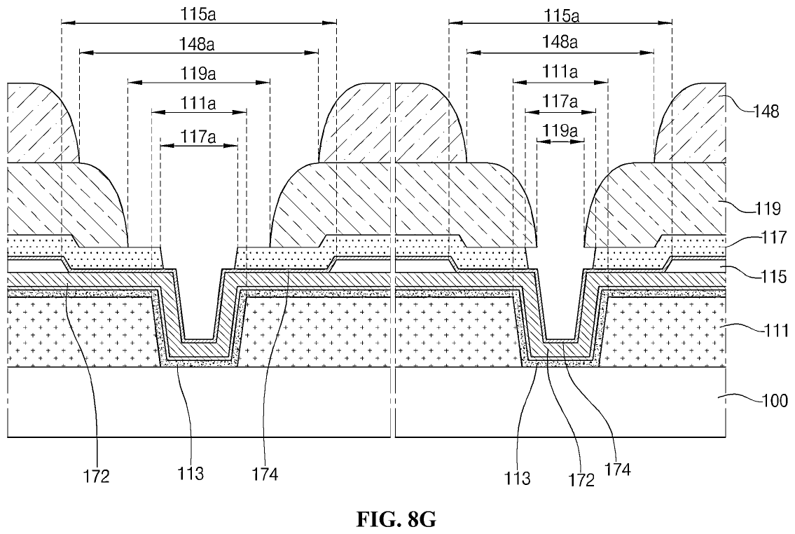

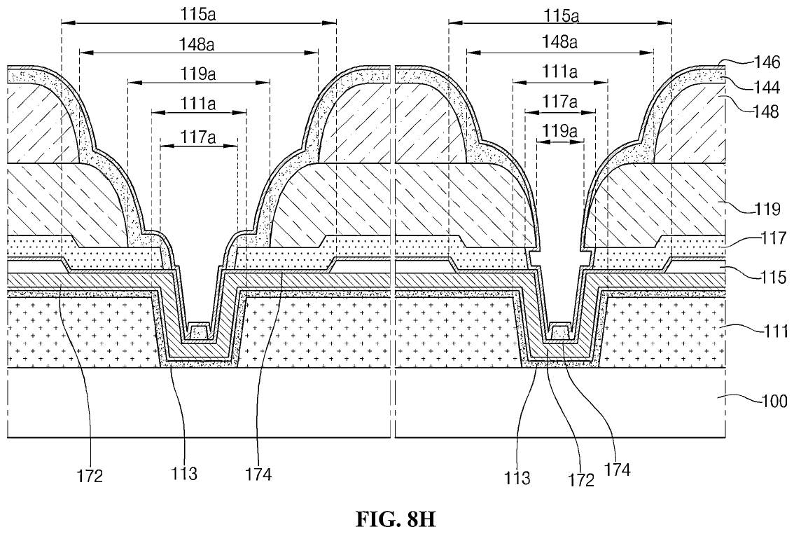

A method of manufacturing the electroluminescent display device according to the first embodiment of the present disclosure will be described in detail with reference to FIGS. 8A to 8H.

FIGS. 8A to 8H are schematic cross-sectional views of a contact area in steps of manufacturing an electroluminescent display device according to the first embodiment of the present disclosure, and will be described with reference to FIG. 5 together.

First, in FIG. 5 and FIG. 8A, the light-blocking layer 152, the power line 162, the data line 166, and the first capacitor electrode 154 can be formed on the substrate 100 by depositing a conductive material and patterning it through a photolithography process. Then, the buffer layer 111 can be formed on the light-blocking layer 152, the power line 162, the data line 166, and the first capacitor electrode 154 by depositing an inorganic insulating material over substantially the entire surface of the substrate 100, and the buffer layer 111 can be patterned through a photolithography process, thereby forming the buffer hole 111a.

Here, the photolithography process can include steps of applying photoresist on a thin film to be patterned, light-exposing and developing the photoresist, etching the thin film, and stripping the photoresist. The etching step can be carried out through a wet etching process using etchant or a dry etching process using gases. When the thin film to be patterned is formed of a material having photosensitivity, only the light-exposing and developing steps can be performed without steps of applying the photoresist and etching the thin film.

Next, in FIG. 5 and FIG. 8B, the first and second semiconductor layers 122 and 132 can be formed on the buffer layer 111 by depositing a semiconductor material and patterning it through a photolithography process, and the gate insulation layer 113 can be formed on the buffer layer 111 provided with the first and second semiconductor layers 122 and 132 thereon by depositing an inorganic insulating material over substantially the entire surface of the substrate 100.

Then, the contact holes exposing the first and second semiconductor layers 122 and 132 of FIG. 5 can be formed by patterning the gate insulation layer 113 through a photolithography process, and the contact holes respectively exposing the power line 162 and the light-blocking layer 152 of FIG. 5 can be formed by patterning the gate insulation layer 113 and the buffer layer 111 through the photolithography process. The gate insulation layer 113 can be in contact with the substrate 100 through the buffer hole 111a.

Next, the first auxiliary electrode 172 can be formed on the gate insulation layer 113 by depositing a conductive material and patterning it through a photolithography process. At this time, the gate insulation layer 113 can also be patterned to have the same shape as the first auxiliary electrode 172. The first auxiliary electrode 172 and the gate insulation layer 113 can overlap the buffer hole 111a and can be formed along the step difference due to the buffer hole 111a. As shown in the figure, the first auxiliary electrode 172 may have an inclined surface due to at least one structure such as the buffer hole 111a.

Here, the first auxiliary electrode 172 and the gate insulation layer 113 can be patterned by a dry etching process. Alternatively, the first auxiliary electrode 172 can be patterned by a wet etching process, and the gate insulation layer 113 can be patterned by a dry etching process. However, embodiments of the present disclosure are not limited thereto.

Meanwhile, the first gate electrode 124, the first source electrode 126, the first drain electrode 128, the second source/drain electrode 137, and the second capacitor electrode 156 of FIG. 5 can also be formed together with the first auxiliary electrode 172.

Next, in FIG. 5 and FIG. 8C, the first passivation layer 115 can be formed on the first auxiliary electrode 172 by depositing an inorganic insulating material, and the first contact hole 115a exposing the first auxiliary electrode 172 can be formed by patterning the first passivation layer 115 through a photolithography process. At this time, the contact hole exposing the first source electrode 126 of FIG. 5 can also be formed together with the first contact hole 115a.

Then, the second auxiliary electrode 174 can be formed on the first passivation layer 115 by depositing a conductive material and patterning it through a photolithography process. At this time, the connection electrode 184 of FIG. 5 can also be formed together with the second auxiliary electrode 174.

The second auxiliary electrode 174 can overlap the first auxiliary electrode 172 and be in contact with the first auxiliary electrode 172 through the first contact hole 115a. In addition, the second auxiliary electrode 174 can overlap the buffer hole 111a and can be formed along the step difference due to the buffer hole 111a.

Next, in FIG. 5 and FIG. 8D, the second passivation layer 117 can be formed on the second auxiliary electrode 174 by depositing an inorganic insulating material, the overcoat layer 119 can be formed on the second passivation layer 117 by applying an organic insulating material, and the third contact hole 119a exposing the second passivation layer 117 can be formed by patterning the overcoat layer 119 through a photolithography process.

The third contact hole 119a can have a smaller area than the first contact hole 115a and can be disposed in the first contact hole 115a. In addition, the width of the third contact hole 119a in one direction can be greater than the width of the buffer hole 111a in the one direction, and the width of the third contact hole 119a in another direction can be smaller than the width of the buffer hole 111a in the another direction. That is, as shown in FIG. 6, the third contact hole 119a can have the cross shape in plan. Thus, the one direction can correspond to the first or second direction, and the another direction can correspond to third or fourth direction crossing the first and second directions.

Here, the overcoat layer 119 can be formed of a material having negative photosensitivity in which a portion exposed to light remains after developing. However, embodiments of the present disclosure are not limited thereto. In other embodiments, the overcoat layer 119 can be formed of a material having positive photosensitivity in which a portion exposed to light is removed after developing.

Meanwhile, when the third contact hole 119a is formed, the overcoat layer 119 corresponding to the transparent area TA of FIG. 5 can also be removed together. In addition, the contact hole exposing the connection electrode 186 can also be formed together with the third contact hole 119a.

Next, in FIG. 5 and FIG. 8E, a photoresist pattern 190 can be formed on the overcoat layer 119 having the third contact hole 119a by applying photoresist and light-exposing and developing it. The photoresist pattern 190 can expose the second passivation layer 117. In the one direction, that is, in the first and second directions, edges of the photoresist pattern 190 can be disposed on the second passivation layer 117, and the photoresist pattern 190 can cover the top and side surfaces of the overcoat layer 119. In the another direction, that is, in the third and fourth directions, edges of the photoresist pattern 190 can be disposed on the overcoat layer 119, and the photoresist pattern 190 can expose the side surface or the top and side surfaces of the overcoat layer 119.

Next, in FIG. 5 and FIG. 8F, the second contact hole 117a exposing the second auxiliary electrode 174 can be formed by selectively removing the exposed second passivation layer 117 using the photoresist pattern 190 as an etch mask. Here, the second passivation layer 117 can be removed through a wet etching process.

The second passivation layer 117 can be over-etched. In this case, even if the second passivation layer 117 under the photoresist pattern 190 in the one direction, that is, in the first and second directions, is over-etched, the width of the second contact hole 117a can be smaller than the width of the third contact hole 119a, so that the undercut structure may not be formed. On the other hand, the second passivation layer 117 under the overcoat layer 119 in the another direction, that is, in the third and fourth directions, can be over-etched, and the width of the second contact hole 117a can be greater than the width of the third contact hole 119a, thereby forming the undercut structure where the bottom surface of the overcoat layer 119 is exposed.

even if, and the width of the second contact hole 117a can be greater than the width of the third contact hole 119a, thereby forming the undercut structure where the bottom surface of the overcoat layer 119 and the bottom surface of the second passivation layer 117 are exposed. On the other hand, in the area where the dummy pattern 164 is not provided,

Meanwhile, the second contact hole 117a can have a smaller area than the buffer hole 111a and the first contact hole 115a and can be disposed in the buffer hole 111a and the first contact hole 115a.

When the second contact hole 117a is formed, the second passivation layer 117 corresponding to the connection electrode 186 of FIG. 5 can also be removed.

Next, in FIG. 5 and FIG. 8G, the photoresist pattern 190 of FIG. 8F can be stripped and removed. Then, the first electrode 142 of FIG. 5 can be formed on the overcoat layer 119 by depositing a conductive material and patterning it through a photolithography process, and the bank 148 having the bank hole 148a can be formed on the first electrode 142 and the overcoat layer 119 by applying an organic insulating material and patterning it through a photolithography process. The bank hole 148a can have a larger area than the buffer hole 111a and the second and third contact holes 117a and 119a, and the buffer hole 111a and the second and third contact holes 117a and 119a can be disposed in the bank hole 148a.

Next, in FIG. 5 and FIG. 8H, the light-emitting layer 144 and the second electrode 146 can be sequentially formed on the first electrode 142, the bank 148, the overcoat layer 119, and the second passivation layer 117. In this case, the light-emitting layer 144 and the second electrode 146 can be formed over substantially the entire surface of the substrate 100 through a vacuum evaporation method and a sputtering method, respectively.

The light-emitting layer 144 can be separated by the buffer hole 111a and the undercut structure to thereby expose the second auxiliary electrode 174 corresponding to the buffer hole 111a and the undercut structure.

On the other hand, the second electrode 146 may not be separated and can be formed to be connected along the buffer hole 111a and the undercut structure, and the second electrode 146 can be in contact with the second auxiliary electrode 174 exposed to correspond to the buffer hole 111a and the undercut structure.

Accordingly, the second electrode 146 can be electrically connected to the first auxiliary electrode 172 through the second auxiliary electrode 174 and be electrically connected to the power line 162 of FIG. 5 through the first auxiliary electrode 172.

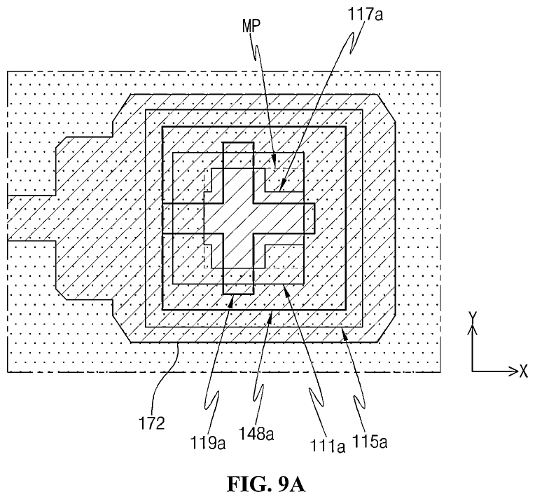

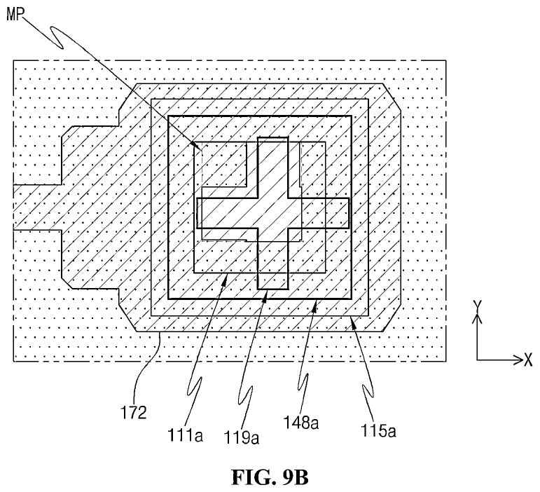

Meanwhile, as described above, in the present disclosure, the third contact hole 119a of the overcoat layer 119 can be configured to have the cross shape, and even if misalignment occurs between the upper layer and the lower layer during the manufacturing process, the second electrode 146 can be in contact with the second auxiliary electrode 174 due to the undercut structure. This will be described with reference to FIGS. 9A and 9B.

FIGS. 9A and 9B are schematic plan views of a contact area of an electroluminescent display device where misalignment occurs according to the first embodiment of the present disclosure. Here, a dotted line MP corresponding to the second contact hole 117a can correspond to a mask pattern for substantially forming the second contact hole 117a.

In FIG. 9A, misalignment can occur when the buffer hole 111a and the third contact hole 119a are formed. That is, the buffer hole 111a and the third contact hole 119a can be formed to be shifted in-X direction. However, the undercut structure can be formed to correspond to each corner of the cross-shaped third contact hole 119a.

In this case, the undercut structure at the right side of the third contact hole 119a can be wider than the undercut structure at the left side of the third contact hole 119a, and the total area of the undercut structure of FIG. 9A can be substantially the same as the total area of the undercut structure where misalignment does not occur.

Meanwhile, in FIG. 9B, misalignment can occur when the second contact hole 117a and the third contact hole 119a are formed. That is, the second contact hole 117a can be formed to be shifted in −X direction and Y direction, and the third contact hole 119a can be formed to be shifted in X direction and −Y direction. However, the undercut structure can be formed to correspond to each corner of the cross-shaped third contact hole 119a.

In this case, the undercut structure at the left and upper sides of the third contact hole 119a can be wider than the undercut structure at the right and lower sides of the third contact hole 119a, and the total area of the undercut structure of FIG. 9B can be substantially the same as the total area of the undercut structure where misalignment does not occur.

As such, even if misalignment occurs, the undercut structure can be formed, and the second electrode 146 can be in contact with the second auxiliary electrode 174. Because the total area of the undercut structure is not changed, a decrease of the contact area between the second electrode 146 and the second auxiliary electrode 174 can be minimized.

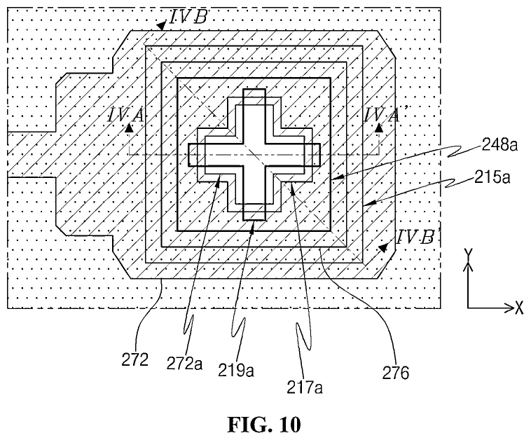

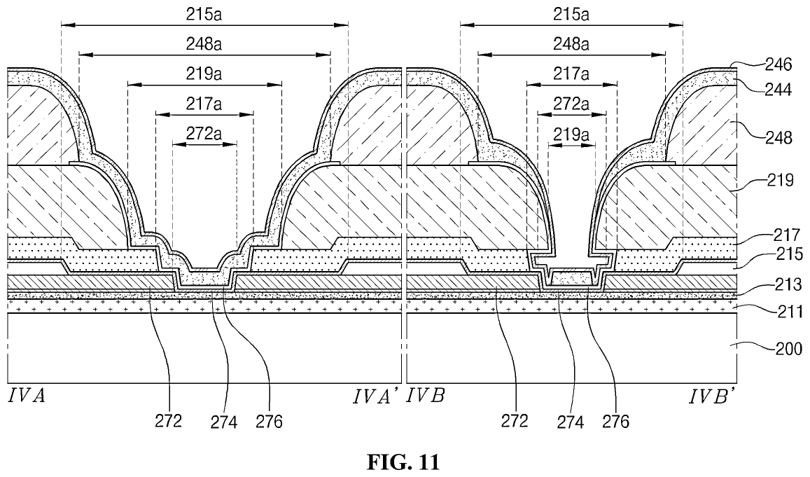

FIG. 10 is a schematic plan view of a contact area of an electroluminescent display device according to a second embodiment of the present disclosure, and FIG. 11 is a cross-sectional view corresponding to the line IVA-IVA′ and the line IVB-IVB′ of FIG. 10. The electroluminescent display device according to the second embodiment of the present disclosure has substantially the same configuration as that of the first embodiment, except for a buffer layer and an auxiliary electrode. The same parts as those of the first embodiment are designated by the same reference signs, and explanation for the same parts may be shortened or omitted.

As shown in FIG. 10 and FIG. 11, in the electroluminescent display device according to the second embodiment of the present disclosure, the buffer layer 211 may not have a buffer hole, the first auxiliary electrode 272 can have an auxiliary hole 272a, and a third auxiliary electrode 276 can be provided between the overcoat layer 219 and the bank 248 and connected to the second electrode 246.

Specifically, the buffer layer 211 can be provided on the substrate 200. The gate insulation layer 213 and the first auxiliary electrode 272 can be sequentially provided on the buffer layer 211.

The first auxiliary electrode 272 can have the auxiliary hole 272a, and the gate insulation layer 213 can be exposed through the auxiliary hole 272a. The auxiliary hole 272a can have a cross shape in plan.

The first passivation layer 215 can be provided on the first auxiliary electrode 272. The first passivation layer 215 can have the first contact hole 215a exposing the top surface of the first auxiliary electrode 272. The first contact hole 215a can have a larger area than the auxiliary hole 272a, and the auxiliary hole 272a can be disposed in the first contact hole 215a. The auxiliary hole 272a may not overlap the first passivation layer 215 and can be spaced apart from the first passivation layer 215 in plan.

The second auxiliary electrode 274 can be provided on the first passivation layer 215. The second auxiliary electrode 274 can be in contact with the first auxiliary electrode 272 exposed through the first contact hole 215a. In addition, the second auxiliary electrode 274 can be in contact with the side surface of the first auxiliary electrode 272 corresponding to the auxiliary hole 272a and also be in contact with the gate insulation layer 213 exposed through the auxiliary hole 272a.

The second auxiliary electrode 274 can have the same shape and the same area as the first auxiliary electrode 272 in plan. The second auxiliary electrode 274 can be omitted.

The second passivation layer 217 can be provided on the second auxiliary electrode 274. The second passivation layer 217 can have the second contact hole 217a exposing the second auxiliary electrode 274.

The second contact hole 217a can have a cross shape in plan and can be disposed in the first contact hole 215a. The second contact hole 217a may not overlap the first passivation layer 215 and can be spaced apart from the first passivation layer 215 in plan.

In addition, the second contact hole 217a can have a larger area than the auxiliary hole 272a, and the auxiliary hole 272a can be disposed in the second contact hole 217a. The auxiliary hole 272a may not overlap the first passivation layer 215 and can be spaced apart from the second passivation layer 217 in plan.

The overcoat layer 219 can be provided on the second passivation layer 217. The overcoat layer 219 can have a substantially flat top surface and have the third contact hole 219a exposing the second passivation layer 217 and the second auxiliary electrode 274.

The third contact hole 219a can include a portion extending in the first direction, which is the X direction, and a portion extending in the second direction, which is the Y direction, to thereby have a cross shape in plan. The third contact hole 219a can have a smaller area than the first contact hole 215a and can be disposed in the first contact hole 215a. The third contact hole 219a may not overlap the first passivation layer 215 and can be spaced apart from the first passivation layer 215 in plan.

Meanwhile, a length of the cross-shaped third contact hole 219a can be greater than a length of the cross-shaped second contact hole 217a, and a width of the cross-shaped third contact hole 219a can be smaller than a width of the cross-shaped second contact hole 217a. Specifically, the length of the portion of the third contact hole 219a extending in the first direction can be greater than the length of the portion of the second contact hole 217a extending in the first direction, and the width of the portion of the third contact hole 219a extending in the first direction can be smaller than the width of the portion of the second contact hole 217a extending in the first direction. In addition, the length of the portion of the third contact hole 219a extending in the second direction can be greater than the length of the portion of the second contact hole 217a extending in the second direction, and the width of the portion of the third contact hole 219a extending in the second direction can be smaller than the width of the portion of the second contact hole 217a extending in the second direction.

Each end of the cross-shaped third contact hole 219a can overlap the second passivation layer 217, and others of the cross-shaped third contact hole 219a excluding the ends can be spaced apart from the second passivation layer 217.

Accordingly, the undercut structure where the bottom surface of the overcoat layer 219 is exposed can be provided between the third contact hole 219a and the second passivation layer 217 spaced apart from each other. The undercut structure can be provided to each corner of the cross-shaped third contact hole 219a. The cross-shaped third contact hole 219a can have an L-like side corresponding to each corner. For example, the cross-shaped third contact hole 219a can have four L-like sides. The undercut structure can be provided to correspond to each L-like side, thereby having an L-like shape in plan. Four undercut structures can be provided to correspond to the third contact hole 219a.

In addition, the length of the cross-shaped third contact hole 219a can be greater than the length of the cross-shaped auxiliary hole 272a, and the width of the cross-shaped third contact hole 219a can be smaller than the width of the cross-shaped auxiliary hole 272a.

The third auxiliary electrode 276 can be provided on the overcoat layer 219. The third auxiliary electrode 276 can have a larger area than the auxiliary hole 272a, the second contact hole 217a, and the third contact hole 219a.

The third auxiliary electrode 276 can be in contact with the top and side surfaces of the overcoat layer 219 and the top and side surfaces of the second passivation layer 217 exposed through the third contact hole 219a. In addition, the third auxiliary electrode 276 can be in contact with the top surface of the second auxiliary electrode 274 exposed through the second contact hole 217a and can also be provided in the auxiliary hole 272a.

The third auxiliary electrode 276 may not be cut off by the undercut structure and can be connected. Accordingly, the third auxiliary electrode 276 can also be in contact with the bottom surface of the overcoat layer 219 exposed by the undercut structure.

The third auxiliary electrode 276 can be formed of indium tin oxide (ITO) or an alloy of molybdenum and titanium (MoTi), but embodiments of the present disclosure are not limited thereto.

The bank 248 can be provided on the third auxiliary electrode 276 and the overcoat layer 219. The bank 248 can have the bank hole 248a exposing the third auxiliary electrode 276. The bank hole 248a can have a smaller area than the third auxiliary electrode 276. Alternatively, the bank hole 248a can have a larger area than the third auxiliary electrode 276.

Further, the bank hole 248a can have a larger area than the auxiliary hole 272a, the second contact hole 217a, and the third contact hole 219a. The auxiliary hole 272a, the second contact hole 217a, and the third contact hole 219a can be disposed in the bank hole 248a.

The light-emitting layer 244 and the second electrode 246 can be sequentially provided on the bank 248. The light-emitting layer 244 and the second electrode 246 can be formed over substantially the entire surface of the substrate 200. The light-emitting layer 244 and the second electrode 246 can cover top and side surfaces of the bank 248 and also cover the third auxiliary electrode 276 exposed through the bank hole 248a. In addition, the light-emitting layer 244 can be in contact with the top and side surfaces of the bank 248 and be in contact with the third auxiliary electrode 276 exposed through the bank hole 248a.

The light-emitting layer 244 can be formed through a thermal evaporation method with relatively low step coverage characteristics. Accordingly, at the side surface of the overcoat layer 219 corresponding to the undercut structure, the light-emitting layer 244 can have a thickness that decreases as it approaches or gets closer to the substrate 200 and then be cut off by the undercut structure. Therefore, the third auxiliary electrode 276 corresponding to the undercut structure can be exposed.

On the other hand, the second electrode 246 can be formed through a sputtering method with relatively high step coverage characteristics. The second electrode 246 may not be cut off by the undercut structure. Accordingly, the second electrode 246 can be in contact with the top surface of the third auxiliary electrode 276 exposed to correspond to the undercut structure, thereby being electrically connected to the first and second auxiliary electrodes 272 and 274 through the third auxiliary electrode 276.

As such, in the electroluminescent display device according to the second embodiment of the present disclosure, the third contact hole 219a of the overcoat layer 219 can be configured to have the cross shape in plan, the undercut structure can be provided to correspond to the third contact hole 219a, and the light-emitting layer 244 can be separated by the undercut structure, so that the second electrode 246 can be in direct contact with the third auxiliary electrode 276. Accordingly, the contact area between the second electrode 246 and the third auxiliary electrode 276 can increase to thereby improve the contact properties between the second electrode 246 and the third auxiliary electrode 276.

In this case, even if misalignment occurs between the upper layer and the lower layer during the manufacturing process, the undercut structure can be provided to correspond to the third contact hole 219a having the cross shape in plan, so that the second electrode 246 can be in contact with the third auxiliary electrode 276.

In addition, by providing the auxiliary hole 272a in the first auxiliary electrode 272 corresponding to the undercut structure, the light-emitting layer 244 can be easily separated by the undercut structure.

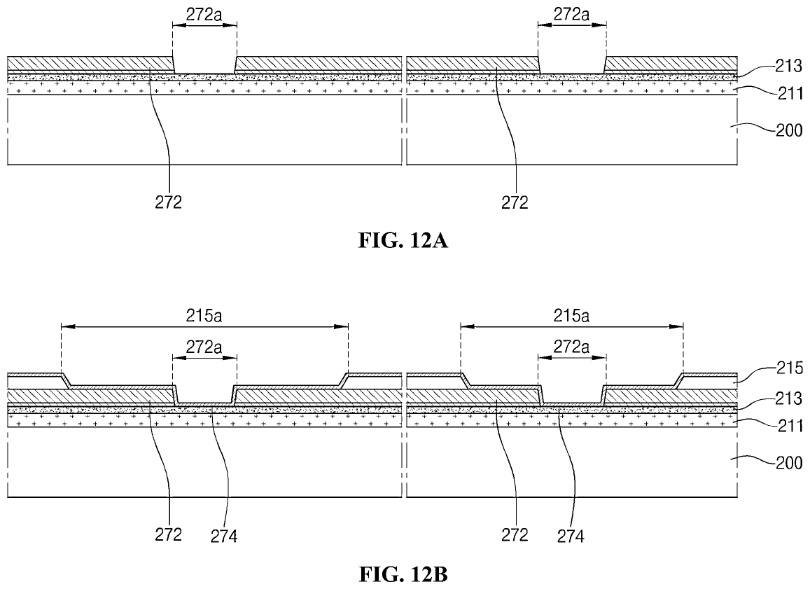

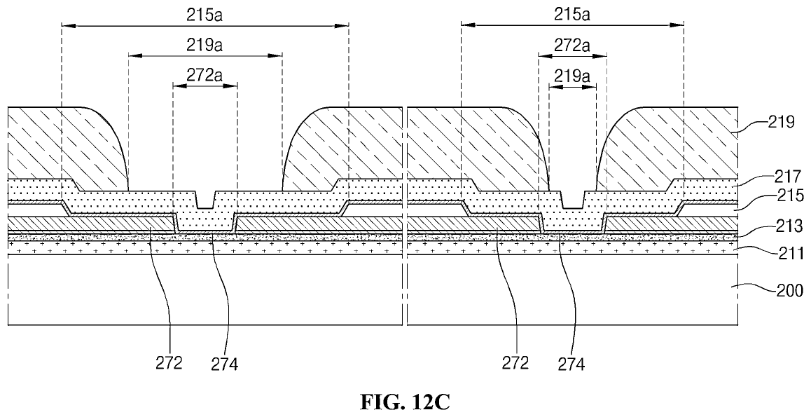

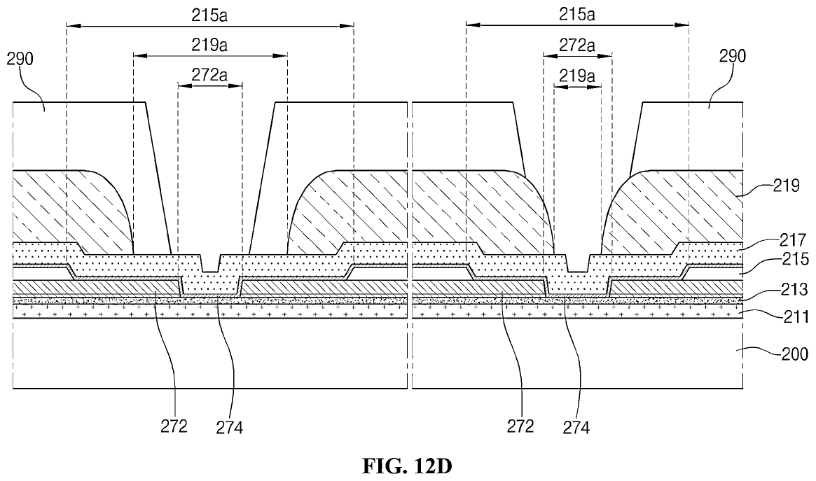

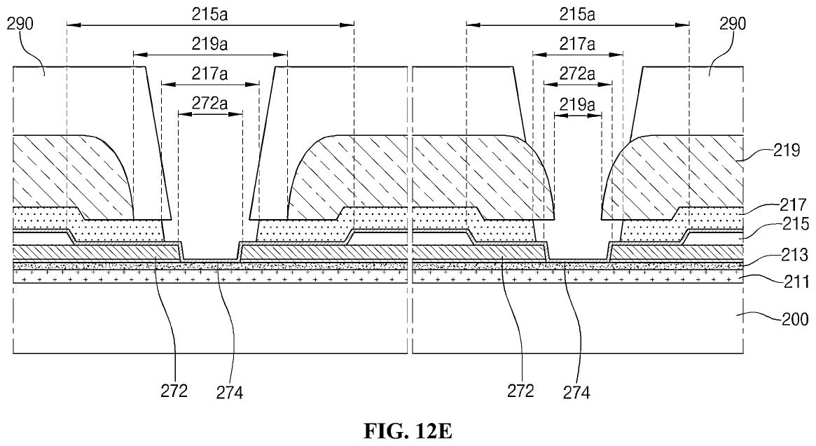

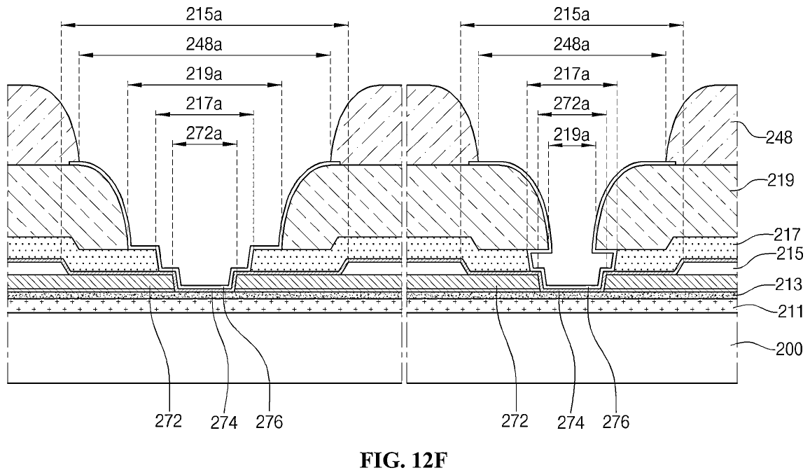

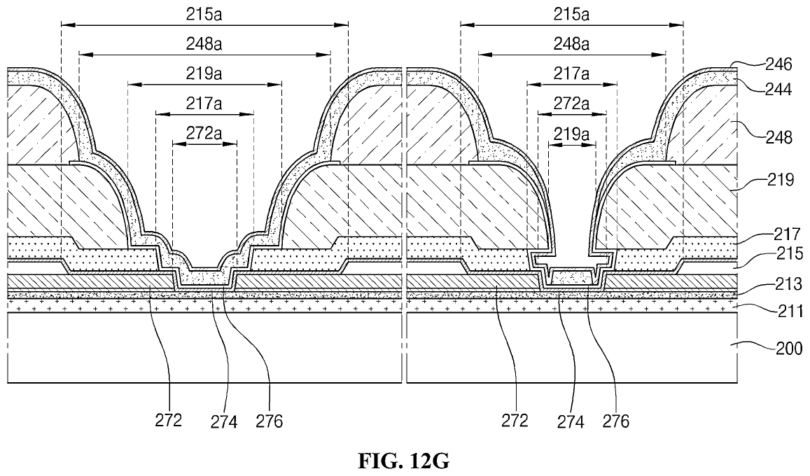

A method of manufacturing the electroluminescent display device according to the second embodiment of the present disclosure will be described in detail with reference to FIGS. 12A to 12G.

FIGS. 12A to 12G are schematic cross-sectional views of a contact area in steps of manufacturing an electroluminescent display device according to the second embodiment of the present disclosure. The method of manufacturing the electroluminescent display device according to the second embodiment of the present disclosure includes substantially the same steps as those of the first embodiment, except for the steps of forming the buffer layer, the first auxiliary electrode, and the third auxiliary electrode. The same parts as those of the first embodiment are designated by the same reference signs, and explanation for the same parts may be shortened or omitted.

First, in FIG. 12A, the buffer layer 211 can be formed on the substrate 200, and the gate insulation layer 213 can be formed on the buffer layer 211. Then, the first auxiliary electrode 272 having the auxiliary hole 272a can be formed on the gate insulation layer 213 by depositing a conductive material and patterning it through a photolithography process.

Next, in FIG. 12B, the first passivation layer 215 can be formed on the first auxiliary electrode 272 by depositing an inorganic insulating material, and then the first passivation layer 215 can be patterned through a photolithography process, thereby forming the first contact hole 215a exposing the first auxiliary electrode 272.

Then, the second auxiliary electrode 274 can be formed on the first passivation layer 215 by depositing a conductive material and patterning it through a photolithography process. The second auxiliary electrode 274 can be in contact with the first auxiliary electrode 272 through the first contact hole 215a and be in contact with the gate insulation layer 213 through the auxiliary hole 272a.

Next, in FIG. 12C, the second passivation layer 217 can be formed on the second auxiliary electrode 274 by depositing an inorganic insulating material, and the overcoat layer 219 can be formed on the second passivation layer 217 by applying an organic insulating material. Then, the overcoat layer 219 can be patterned through a photolithography process, thereby forming the third contact hole 219a exposing the second passivation layer 217.

Next, in FIG. 12D, photoresist can be applied on the overcoat layer 219 having the third contact hole 219a, be exposed to light, and be developed, thereby forming a photoresist pattern 290 exposing the second passivation layer 217. In the one direction, that is, in the first and second directions of FIG. 10, edges of the photoresist pattern 290 can be disposed on the second passivation layer 217, and the photoresist pattern 290 can cover the top and side surfaces of the overcoat layer 219. In the another direction, that is, in the third and fourth directions crossing the first and second directions of FIG. 10, edges of the photoresist pattern 290 can be disposed on the overcoat layer 219, and the photoresist pattern 290 can expose the side surface or the top and side surfaces of the overcoat layer 219.

Next, in FIG. 12E, the second contact hole 217a exposing the second auxiliary electrode 274 can be formed by selectively removing the exposed second passivation layer 217 using the photoresist pattern 290 as an etch mask.

The second passivation layer 217 can be over-etched. In this case, even if the second passivation layer 217 under the photoresist pattern 290 in the one direction, that is, in the first and second directions, is over-etched, the width of the second contact hole 217a can be smaller than the width of the third contact hole 219a, so that the undercut structure may not be formed. On the other hand, the second passivation layer 217 under the overcoat layer 219 in the another direction, that is, in the third and fourth directions, can be over-etched, and the width of the second contact hole 217a can be greater than the width of the third contact hole 219a, thereby forming the undercut structure where the bottom surface of the overcoat layer 219 is exposed.

Next, in FIG. 12F, the photoresist pattern 290 of FIG. 12G can be stripped and removed. Then, the third auxiliary electrode 276 can be formed on the overcoat layer 219 by depositing a conductive material and patterning it through a photolithography process. The third auxiliary electrode 276 can be in contact with the second auxiliary electrode 274 exposed through the second and third contact holes 217a and 219a and can also be disposed in the auxiliary hole 272a.

Then, the bank 248 having the bank hole 248a can be formed on the third auxiliary electrode 276 by applying an organic insulating material and patterning it through a photolithography process. The third auxiliary electrode 276 can be exposed through the bank hole 248a.

Next, in FIG. 12G, the light-emitting layer 244 and the second electrode 246 can be sequentially formed on the bank 248 and the third auxiliary electrode 276. In this case, the light-emitting layer 244 and the second electrode 246 can be formed over substantially the entire surface of the substrate 200 through a vacuum evaporation method and a sputtering method, respectively.

The light-emitting layer 244 can be separated by the undercut structure to thereby expose the third auxiliary electrode 276 corresponding to the undercut structure.

On the other hand, the second electrode 246 may not be separated and can be formed to be connected along the undercut structure, and the second electrode 246 can be in contact with the third auxiliary electrode 276 exposed to correspond to the undercut structure.

Accordingly, the second electrode 246 can be electrically connected to the first and second auxiliary electrodes 272 and 274 through the third auxiliary electrode 276.

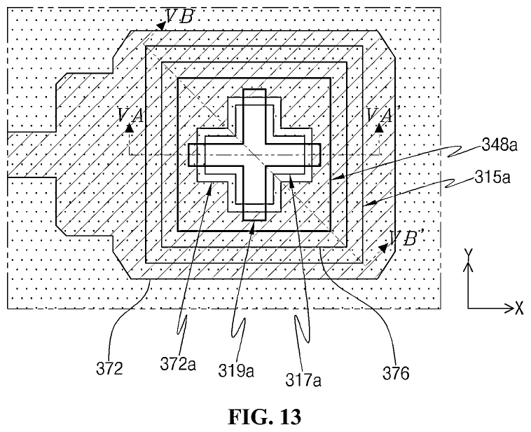

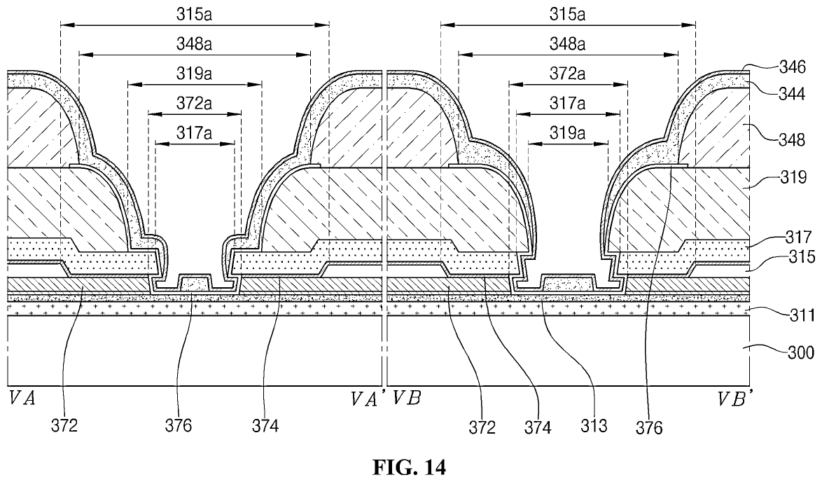

FIG. 13 is a schematic plan view of a contact area of an electroluminescent display device according to a third embodiment of the present disclosure, and FIG. 14 is a cross-sectional view corresponding to the line VA-VA′ and the line VB-VB′ of FIG. 13. The electroluminescent display device according to the third embodiment of the present disclosure has substantially the same configuration as that of the first and second embodiments, except for an auxiliary hole. The same parts as those of the first and second embodiments are designated by the same reference signs, and explanation for the same parts may be shortened or omitted.

As shown in FIG. 13 and FIG. 14, in the electroluminescent display device according to the third embodiment of the present disclosure, the auxiliary hole 372a of the first auxiliary electrode 372 can have a larger area than the second contact hole 317a of the second passivation layer 317.

Specifically, the buffer layer 311 can be provided on the substrate 300. The gate insulation layer 313 and the first auxiliary electrode 372 can be sequentially provided on the buffer layer 311.

The first auxiliary electrode 372 can have the auxiliary hole 372a, and the gate insulation layer 313 can be exposed through the auxiliary hole 372a. The auxiliary hole 372a can have a cross shape in plan.

The first passivation layer 315 can be provided on the first auxiliary electrode 372. The first passivation layer 315 can have the first contact hole 315a exposing the top surface of the first auxiliary electrode 372. The first contact hole 315a can have a larger area than the auxiliary hole 372a, and the auxiliary hole 372a can be disposed in the first contact hole 315a. The auxiliary hole 372a may not overlap the first passivation layer 315 and can be spaced apart from the first passivation layer 315 in plan.

The second auxiliary electrode 374 can be provided on the first passivation layer 315. The second auxiliary electrode 374 can be in contact with the first auxiliary electrode 372 exposed through the first contact hole 315a. In addition, the second auxiliary electrode 374 can have a hole corresponding to the auxiliary hole 372a.

The second auxiliary electrode 374 can have the same shape and the same area as the first auxiliary electrode 372 in plan. The second auxiliary electrode 374 can be omitted.

The second passivation layer 317 can be provided on the second auxiliary electrode 374. The second passivation layer 317 can have the second contact hole 317a exposing the auxiliary hole 372a.

The second contact hole 317a can have a cross shape in plan and can be disposed in the first contact hole 315a. The second contact hole 317a may not overlap the first passivation layer 315 and can be spaced apart from the first passivation layer 315 in plan.

In addition, the second contact hole 317a can have a smaller area than the auxiliary hole 372a and can be disposed in the auxiliary hole 372a. The second contact hole 317a may not overlap the first auxiliary electrode 372 and can be spaced apart from the first auxiliary electrode 372 in plan.

Accordingly, a first undercut structure where the bottom surface of the second passivation layer 317 is exposed can be provided between the second contact hole 317a and the first auxiliary electrode 372 spaced apart from each other. The first undercut structure can be provided along edges of the second contact hole 317a having a cross shape.

The overcoat layer 319 can be provided on the second passivation layer 317. The overcoat layer 319 can have a substantially flat top surface and have the third contact hole 319a exposing the second passivation layer 317.

The third contact hole 319a can include a portion extending in the first direction, which is the X direction, and a portion extending in the second direction, which is the Y direction, to thereby have a cross shape in plan. The third contact hole 319a can have a smaller area than the first contact hole 315a and can be disposed in the first contact hole 315a. The third contact hole 319a may not overlap the first passivation layer 315 and can be spaced apart from the first passivation layer 315 in plan.

Meanwhile, a length of the cross-shaped third contact hole 319a can be greater than a length of the cross-shaped second contact hole 317a, and a width of the cross-shaped third contact hole 319a can be smaller than a width of the cross-shaped second contact hole 317a. Specifically, the length of the portion of the third contact hole 319a extending in the first direction can be greater than the length of the portion of the second contact hole 317a extending in the first direction, and the width of the portion of the third contact hole 319a extending in the first direction can be smaller than the width of the portion of the second contact hole 317a extending in the first direction. In addition, the length of the portion of the third contact hole 319a extending in the second direction can be greater than the length of the portion of the second contact hole 317a extending in the second direction, and the width of the portion of the third contact hole 319a extending in the second direction can be smaller than the width of the portion of the second contact hole 317a extending in the second direction.

Each end of the cross-shaped third contact hole 319a can overlap the second passivation layer 317, and others of the cross-shaped third contact hole 319a excluding the ends can be spaced apart from the second passivation layer 317.

Accordingly, a second undercut structure where the bottom surface of the overcoat layer 319 is exposed can be provided between the third contact hole 319a and the second passivation layer 317 spaced apart from each other. The second undercut structure can be provided to each corner of the cross-shaped third contact hole 319a. The cross-shaped third contact hole 319a can have an L-like side corresponding to each corner. For example, the cross-shaped third contact hole 319a can have four L-like sides. The second undercut structure can be provided to correspond to each L-like side, thereby having an L-like shape in plan. Four second undercut structures can be provided to correspond to the third contact hole 319a.

In addition, the length of the cross-shaped third contact hole 319a can be greater than the length of the cross-shaped auxiliary hole 372a, and the width of the cross-shaped third contact hole 319a can be smaller than the width of the cross-shaped auxiliary hole 372a.

The third auxiliary electrode 376 can be provided on the overcoat layer 319. The third auxiliary electrode 376 can have a larger area than the auxiliary hole 372a, the second contact hole 317a, and the third contact hole 319a.

The third auxiliary electrode 376 can be in contact with the top and side surfaces of the overcoat layer 319 and the top and side surfaces of the second passivation layer 317 exposed through the third contact hole 319a. In addition, the third auxiliary electrode 376 can be in contact with the side surfaces of the first and second auxiliary electrodes 372 and 374 exposed through the second contact hole 317a and the auxiliary hole 372a and be in contact with the top surface of the gate insulation layer 313.

The third auxiliary electrode 376 may not be cut off by the first and second undercut structures and can be connected. Accordingly, the third auxiliary electrode 376 can also be in contact with the bottom surface of the second passivation layer 317 exposed by the first undercut structure and the bottom surface of the overcoat layer 319 exposed by the second undercut structure.

The bank 348 can be provided on the third auxiliary electrode 376 and the overcoat layer 319. The bank 348 can have the bank hole 348a exposing the third auxiliary electrode 376. The bank hole 348a can have a smaller area than the third auxiliary electrode 376. Alternatively, the bank hole 348a can have a larger area than the third auxiliary electrode 376.

Further, the bank hole 348a can have a larger area than the auxiliary hole 372a, the second contact hole 317a, and the third contact hole 319a. The auxiliary hole 372a, the second contact hole 317a, and the third contact hole 319a can be disposed in the bank hole 348a.

The light-emitting layer 344 and the second electrode 346 can be sequentially provided on the bank 348. The light-emitting layer 344 and the second electrode 346 can be formed over substantially the entire surface of the substrate 300. The light-emitting layer 344 and the second electrode 346 can cover the top and side surfaces of the bank 348 and also cover the third auxiliary electrode 376 exposed through the bank hole 348a. In addition, the light-emitting layer 344 can be in contact with the top and side surfaces of the bank 348 and be in contact with the third auxiliary electrode 376 exposed through the bank hole 348a.

The light-emitting layer 344 can be formed through a thermal evaporation method with relatively low step coverage characteristics. Accordingly, at the side surface of the overcoat layer 319 corresponding to the second undercut structure, the light-emitting layer 344 can have a thickness that decreases as it approaches or gets closer to the substrate 300 and then be cut off by the second undercut structure. Therefore, the third auxiliary electrode 376 corresponding to the second undercut structure can be exposed.

Further, in an area where the second undercut structure is not provided, at the side surface of the second passivation layer 317 corresponding to the first undercut structure, the light-emitting layer 344 can have a thickness that decreases as it approaches or gets closer to the substrate 300 and then be cut off by the first undercut structure. Therefore, the third auxiliary electrode 376 corresponding to the first undercut structure can be exposed.

On the other hand, the second electrode 346 can be formed through a sputtering method with relatively high step coverage characteristics. The second electrode 346 may not be cut off by the first and second undercut structures. Accordingly, the second electrode 346 can be in contact with the top surface of the third auxiliary electrode 376 exposed to correspond to the first and second undercut structures, thereby being electrically connected to the first and second auxiliary electrodes 372 and 374 through the third auxiliary electrode 376.

As such, in the electroluminescent display device according to the third embodiment of the present disclosure, the first and second undercut structures can be provided to correspond to the second and third contact holes 317a and 319a having the cross shape, respectively, and the light-emitting layer 344 can be separated by the first and second undercut structures, so that the second electrode 346 can be in direct contact with the third auxiliary electrode 376. Accordingly, the contact area between the second electrode 346 and the third auxiliary electrode 376 can increase to thereby improve the contact properties between the second electrode 346 and the third auxiliary electrode 376.

In this case, even if misalignment occurs between the upper layer and the lower layer during the manufacturing process, the first and second undercut structures can be provided to correspond to the second and third contact holes 317a and 319a having the cross shape in plan, so that the second electrode 346 can be in contact with the third auxiliary electrode 376.

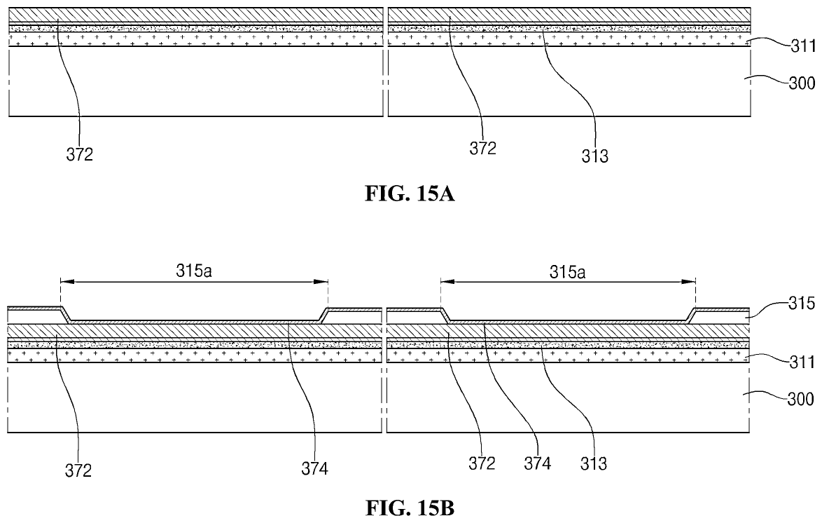

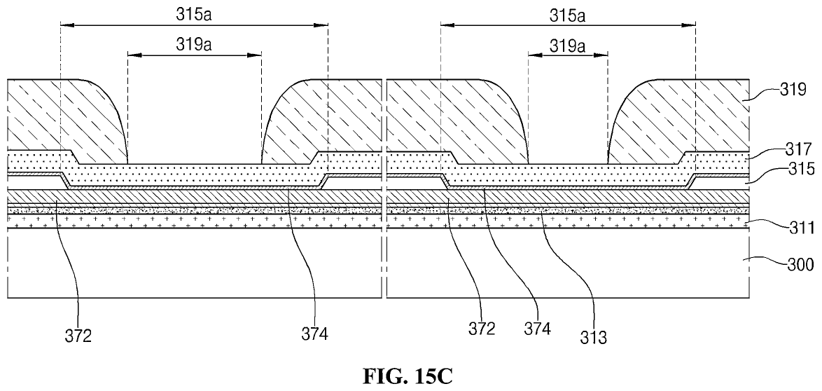

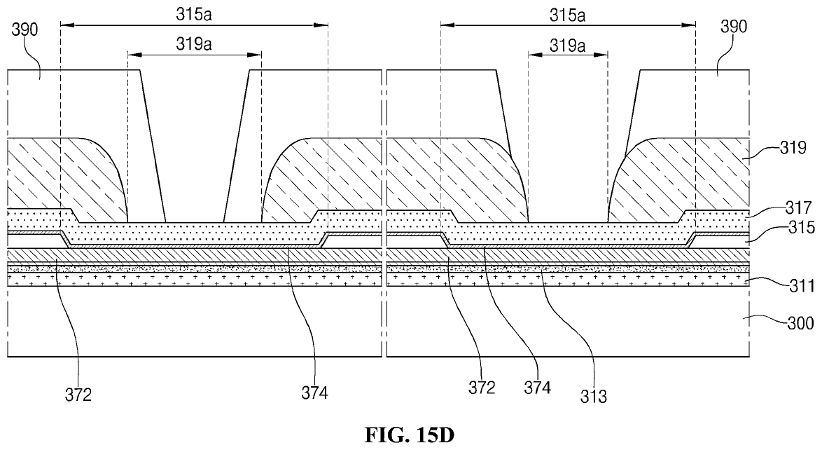

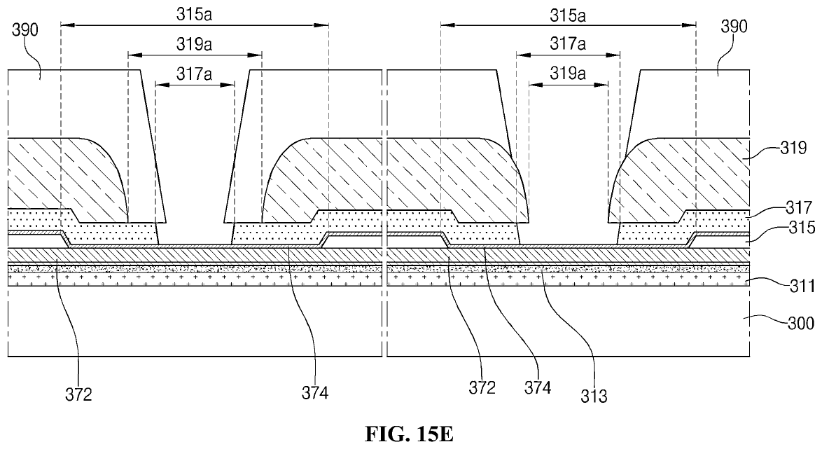

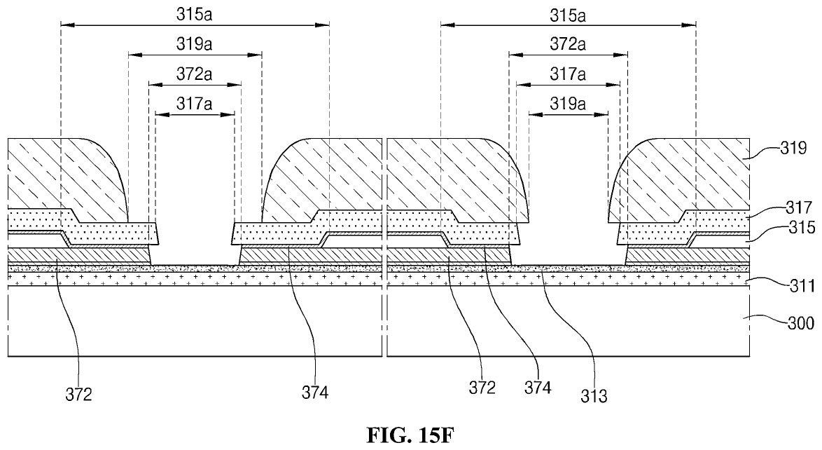

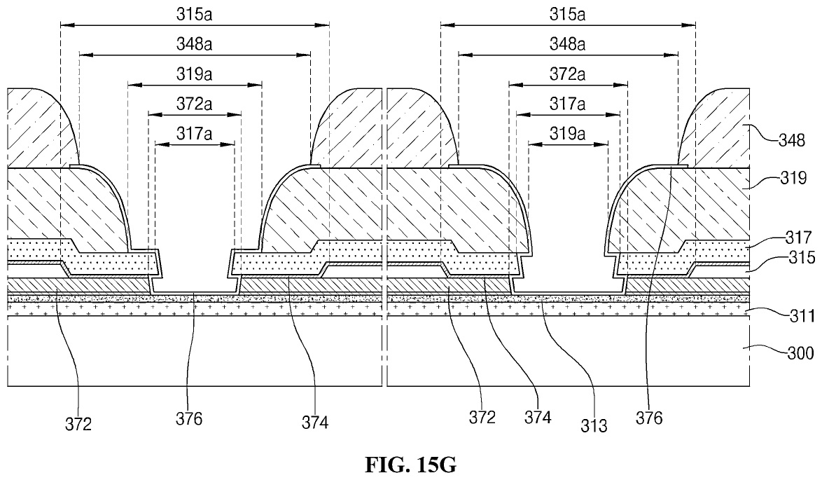

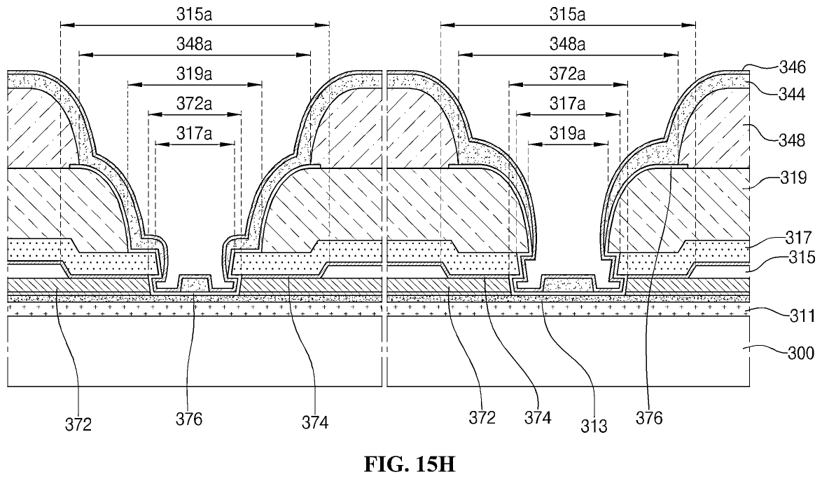

A method of manufacturing the electroluminescent display device according to the third embodiment of the present disclosure will be described in detail with reference to FIGS. 15A to 15H.

FIGS. 15A to 15H are schematic cross-sectional views of a contact area in steps of manufacturing an electroluminescent display device according to the third embodiment of the present disclosure. The method of manufacturing the electroluminescent display device according to the third embodiment of the present disclosure includes substantially the same steps as those of the first and second embodiments, except for the step of forming the buffer hole. The same parts as those of the first and second embodiments are designated by the same reference signs, and explanation for the same parts may be shortened or omitted.

First, in FIG. 15A, the buffer layer 311 can be formed on the substrate 300, and the gate insulation layer 313 can be formed on the buffer layer 311. Then, the first auxiliary electrode 372 can be formed on the gate insulation layer 313 by depositing a conductive material and patterning it through a photolithography process.

Next, in FIG. 15B, the first passivation layer 315 can be formed on the first auxiliary electrode 372 by depositing an inorganic insulating material, and then the first passivation layer 215 can be patterned through a photolithography process, thereby forming the first contact hole 315a exposing the first auxiliary electrode 372.

Then, the second auxiliary electrode 374 can be formed on the first passivation layer 315 by depositing a conductive material and patterning it through a photolithography process. The second auxiliary electrode 374 can be in contact with the first auxiliary electrode 372 through the first contact hole 315a.

Next, in FIG. 15C, the second passivation layer 317 can be formed on the second auxiliary electrode 374 by depositing an inorganic insulating material, and the overcoat layer 319 can be formed on the second passivation layer 317 by applying an organic insulating material. Then, the overcoat layer 319 can be patterned through a photolithography process, thereby forming the third contact hole 319a exposing the second passivation layer 317.

Next, in FIG. 15D, photoresist can be applied on the overcoat layer 319 having the third contact hole 319a, be exposed to light, and be developed, thereby forming a photoresist pattern 390 exposing the second passivation layer 317. In one direction, that is, in the first and second directions of FIG. 13, edges of the photoresist pattern 390 can be disposed on the second passivation layer 317, and the photoresist pattern 390 can cover the top and side surfaces of the overcoat layer 319. In another direction, that is, in the third and fourth directions crossing the first and second directions of FIG. 13, edges of the photoresist pattern 390 can be disposed on the overcoat layer 319, and the photoresist pattern 390 can expose the side surface or the top and side surfaces of the overcoat layer 319.

Next, in FIG. 15E, the second contact hole 317a exposing the second auxiliary electrode 374 can be formed by selectively removing the exposed second passivation layer 317 using the photoresist pattern 390 as an etch mask.

The second passivation layer 317 can be over-etched. In this case, even if the second passivation layer 317 under the photoresist pattern 390 in the one direction, that is, in the first and second directions, is over-etched, the width of the second contact hole 317a can be smaller than the width of the third contact hole 319a, so that the undercut structure may not be formed. On the other hand, the second passivation layer 317 under the overcoat layer 319 in the another direction, that is, in the third and fourth directions, can be over-etched, and the width of the second contact hole 317a can be greater than the width of the third contact hole 319a, thereby forming the second undercut structure where the bottom surface of the overcoat layer 319 is exposed.

Next, in FIG. 15F, the auxiliary hole 372a exposing the gate insulation layer 313 can be formed by selectively removing the second auxiliary electrode 374 exposed through the second contact hole 317a and the first auxiliary electrode 372 thereunder using the second passivation layer 317 with the second contact hole 317a as an etching mask.

In this case, the first and second auxiliary electrodes 372 and 374 disposed under the second passivation layer 317 can be over-etched. Accordingly, the width of the auxiliary hole 372a can be greater than the width of the second contact hole 317a, thereby forming the first undercut structure where the bottom surface of the second passivation layer 317 is exposed.

Then, the photoresist pattern 390 of FIG. 15E can be stripped and removed.

Next, in FIG. 15G, the third auxiliary electrode 376 can be formed on the overcoat layer 319 by depositing a conductive material and patterning it through a photolithography process. The third auxiliary electrode 376 can be in contact with the side surfaces of the first and second auxiliary electrodes 372 and 374 and the top surface of the gate insulation layer 313 exposed through the second contact hole 317a and the auxiliary hole 372a.

Then, the bank 348 having the bank hole 348a can be formed on the third auxiliary electrode 376 by applying an organic insulating material and patterning it through a photolithography process. The third auxiliary electrode 376 can be exposed through the bank hole 348a.

Next, in FIG. 15H, the light-emitting layer 344 and the second electrode 346 can be sequentially formed on the bank 348 and the third auxiliary electrode 376. In this case, the light-emitting layer 344 and the second electrode 346 can be formed over substantially the entire surface of the substrate 300 through a vacuum evaporation method and a sputtering method, respectively.

The light-emitting layer 344 can be separated by the first and second undercut structures to thereby expose the third auxiliary electrode 376 corresponding to the first and second undercut structures.

On the other hand, the second electrode 346 may not be separated and can be formed to be connected along the first and second undercut structures, and the second electrode 346 can be in contact with the third auxiliary electrode 376 exposed to correspond to the first and second undercut structures.

Accordingly, the second electrode 346 can be electrically connected to the first and second auxiliary electrodes 372 and 374 through the third auxiliary electrode 376.

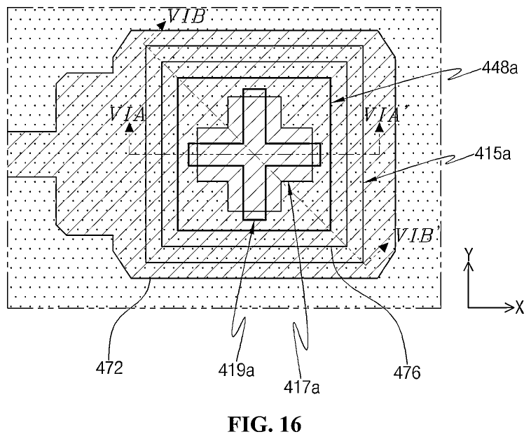

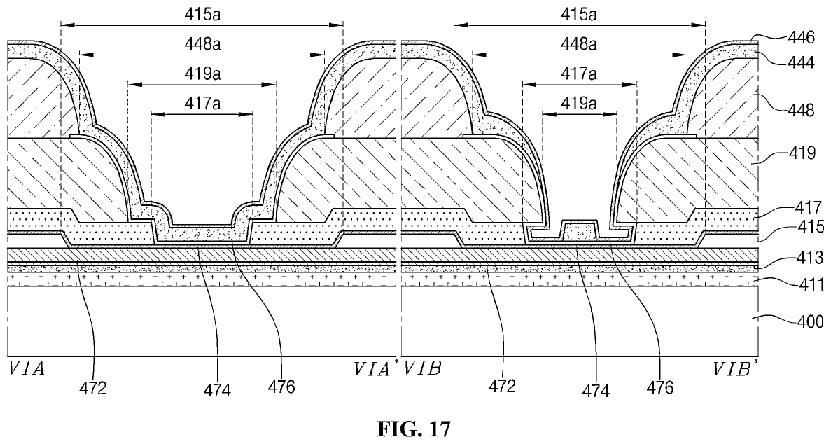

FIG. 16 is a schematic plan view of a contact area of an electroluminescent display device according to a fourth embodiment of the present disclosure, and FIG. 17 is a cross-sectional view corresponding to the line VIA-VIA′ and the line VIB-VIB′ of FIG. 16. The electroluminescent display device according to the fourth embodiment of the present disclosure has substantially the same configuration as that of the first, second, and third embodiments, except for the auxiliary electrode. The same parts as those of the first, second, and third embodiments are designated by the same reference signs, and explanation for the same parts may be shortened or omitted.

As shown in FIG. 16 and FIG. 17, in the electroluminescent display device according to the fourth embodiment of the present disclosure, the buffer layer 411 may not have the buffer hole, the first auxiliary electrode 472 may not have the auxiliary hole, and the third auxiliary electrode 476 can be provided between the overcoat layer 419 and the bank 448 and be connected to the second electrode 446.

Specifically, the buffer layer 411 can be provided on the substrate 400. The gate insulation layer 413 and the first auxiliary electrode 472 can be sequentially provided on the buffer layer 411.

The first passivation layer 415 can be provided on the first auxiliary electrode 472. The first passivation layer 415 can have the first contact hole 415a exposing the top surface of the first auxiliary electrode 472.

The second auxiliary electrode 474 can be provided on the first passivation layer 415. The second auxiliary electrode 474 can be in contact with the first auxiliary electrode 472 exposed through the first contact hole 415a.

The second auxiliary electrode 474 can have the same shape and the same area as the first auxiliary electrode 472 in plan. The second auxiliary electrode 474 can be omitted.

The second passivation layer 417 can be provided on the second auxiliary electrode 474. The second passivation layer 417 can have the second contact hole 417a exposing the second auxiliary electrode 474.

The second contact hole 417a can have a cross shape in plan and can be disposed in the first contact hole 415a. The second contact hole 417a may not overlap the first passivation layer 415 and can be spaced apart from the first passivation layer 415 in plan.

The overcoat layer 419 can be provided on the second passivation layer 417. The overcoat layer 419 can have a substantially flat top surface and have the third contact hole 419a exposing the second passivation layer 417 and the second auxiliary electrode 474.

The third contact hole 419a can include a portion extending in the first direction, which is the X direction, and a portion extending in the second direction, which is the Y direction, to thereby have a cross shape in plan. The third contact hole 419a can have a smaller area than the first contact hole 415a and can be disposed in the first contact hole 415a. The third contact hole 419a may not overlap the first passivation layer 415 and can be spaced apart from the first passivation layer 415 in plan.

Meanwhile, a length of the cross-shaped third contact hole 419a can be greater than a length of the cross-shaped second contact hole 417a, and a width of the cross-shaped third contact hole 419a can be smaller than a width of the cross-shaped second contact hole 417a. Specifically, the length of the portion of the third contact hole 419a extending in the first direction can be greater than the length of the portion of the second contact hole 417a extending in the first direction, and the width of the portion of the third contact hole 419a extending in the first direction can be smaller than the width of the portion of the second contact hole 417a extending in the first direction. In addition, the length of the portion of the third contact hole 419a extending in the second direction can be greater than the length of the portion of the second contact hole 417a extending in the second direction, and the width of the portion of the third contact hole 419a extending in the second direction can be smaller than the width of the portion of the second contact hole 417a extending in the second direction.

Each end of the cross-shaped third contact hole 419a can overlap the second passivation layer 417, and others of the cross-shaped third contact hole 419a excluding the ends can be spaced apart from the second passivation layer 417.

Accordingly, the undercut structure where the bottom surface of the overcoat layer 419 is exposed can be provided between the third contact hole 419a and the second passivation layer 417 spaced apart from each other. The undercut structure can be provided to each corner of the cross-shaped third contact hole 419a. The cross-shaped third contact hole 419a can have an L-like side corresponding to each corner. For example, the cross-shaped third contact hole 419a can have four L-like sides. The undercut structure can be provided to correspond to each L-like side, thereby having an L-like shape in plan. Four undercut structures can be provided to correspond to the third contact hole 419a.

The third auxiliary electrode 476 can be provided on the overcoat layer 419. The third auxiliary electrode 476 can have a larger area than the auxiliary hole 472a, the second contact hole 417a, and the third contact hole 419a.

The third auxiliary electrode 476 can be in contact with the top and side surfaces of the overcoat layer 419 and the top and side surfaces of the second passivation layer 417 exposed through the third contact hole 419a. In addition, the third auxiliary electrode 476 can be in contact with the top surface of the second auxiliary electrode 474 exposed through the second contact hole 417a.

The third auxiliary electrode 476 may not be cut off by the undercut structure and can be connected. Accordingly, the third auxiliary electrode 476 can also be in contact with the bottom surface of the overcoat layer 419 exposed by the undercut structure.

The third auxiliary electrode 476 can be formed of indium tin oxide (ITO) or an alloy of molybdenum and titanium (MoTi), but embodiments of the present disclosure are not limited thereto.

The bank 448 can be provided on the third auxiliary electrode 476 and the overcoat layer 419. The bank 448 can have the bank hole 448a exposing the third auxiliary electrode 476. The bank hole 448a can have a smaller area than the third auxiliary electrode 476. Alternatively, the bank hole 448a can have a larger area than the third auxiliary electrode 476.

Further, the bank hole 448a can have a larger area than the second contact hole 417a and the third contact hole 419a. The second contact hole 417a and the third contact hole 419a can be disposed in the bank hole 448a.

The light-emitting layer 444 and the second electrode 446 can be sequentially provided on the bank 448. The light-emitting layer 444 and the second electrode 446 can be formed over substantially the entire surface of the substrate 400. The light-emitting layer 444 and the second electrode 446 can cover the top and side surfaces of the bank 448 and also cover the third auxiliary electrode 476 exposed through the bank hole 448a. In addition, the light-emitting layer 444 can be in contact with the top and side surfaces of the bank 448 and be in contact with the third auxiliary electrode 476 exposed through the bank hole 448a.

The light-emitting layer 444 can be formed through a thermal evaporation method with relatively low step coverage characteristics. Accordingly, at the side surface of the overcoat layer 419 corresponding to the undercut structure, the light-emitting layer 444 can have a thickness that decreases as it approaches or gets closer to the substrate 400 and then be cut off by the undercut structure. Therefore, the third auxiliary electrode 476 corresponding to the undercut structure can be exposed.

On the other hand, the second electrode 446 can be formed through a sputtering method with relatively high step coverage characteristics. The second electrode 446 may not be cut off by the undercut structure. Accordingly, the second electrode 446 can be in contact with the top surface of the third auxiliary electrode 476 exposed to correspond to the undercut structure, thereby being electrically connected to the first and second auxiliary electrodes 572 and 574 through the third auxiliary electrode 476.

As such, in the electroluminescent display device according to the fourth embodiment of the present disclosure, the third contact hole 419a of the overcoat layer 419 can be configured to have the cross shape in plan, the undercut structure can be provided to correspond to the third contact holes 419a, and the light-emitting layer 444 can be separated by the undercut structure, so that the second electrode 446 can be in direct contact with the third auxiliary electrode 476. Accordingly, the contact area between the second electrode 446 and the third auxiliary electrode 476 can increase to thereby improve the contact properties between the second electrode 446 and the third auxiliary electrode 476.

In this case, even if misalignment occurs between the upper layer and the lower layer during the manufacturing process, the undercut structure can be provided to correspond to the third contact hole 419a having the cross shape in plan, so that the second electrode 446 can be in contact with the third auxiliary electrode 476.

A method of manufacturing the electroluminescent display device according to the fourth embodiment of the present disclosure can differ from the method of manufacturing the electroluminescent display device according to the second embodiment in that the step of forming the auxiliary hole 272a of the first auxiliary electrode 272 is omitted. That is, the electroluminescent display device according to the fourth embodiment of the present disclosure can be manufactured by substantially the same method as the electroluminescent display device according to the second embodiment shown in FIGS. 12A to 12G, except for the step of forming the auxiliary hole 272a in FIG. 12A.

In the electroluminescent display device of the present disclosure, by connecting the second electrode of the light-emitting diode to the power line through the auxiliary electrode, the resistance of the second electrode can be reduced, and the luminance of the electroluminescent display device can be uniform.

In addition, by providing the undercut structure corresponding to the contact hole having the cross shape in plan, the light-emitting layer can be separated by the undercut structure to thereby expose the auxiliary electrode, and the second electrode can be in contact with the exposed auxiliary electrode, so that the contact area between the second electrode and the auxiliary electrode can increase, thereby improving the contact property between the second electrode and the auxiliary electrode.

Further, even if misalignment occurs during the manufacturing process, the total area of the undercut structure may not be substantially changed, and thus it is possible to minimize a decrease of the contact area between the second electrode and the auxiliary electrode.

Moreover, by providing the hole in the auxiliary electrode or the buffer layer or further forming another auxiliary electrode covering the undercut structure, the contact area between the second electrode and the auxiliary electrode can be increased.

Accordingly, the luminance of the electroluminescent display device can be improved, and the improved luminance can reduce power consumption, thereby achieving the low power consumption.

It will be apparent to those skilled in the art that various modifications and variations can be made in the electroluminescent display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. An electroluminescent display device, comprising:
a substrate provided with a sub-pixel including an emission area and a contact area;
a light-emitting diode provided in the emission area over the substrate and including a first electrode, a light-emitting layer, and a second electrode;
a first auxiliary electrode provided in the contact area over the substrate and connected to the second electrode; and
an insulation layer between the first auxiliary electrode and the light-emitting diode and having a contact hole exposing the first auxiliary electrode,
wherein the contact hole includes a portion extending in a first direction and a portion extending in a second direction, and an undercut structure where a bottom surface of the insulation layer is exposed is provided at at least one side of the contact hole, and
wherein the light-emitting layer is cut off by the undercut structure, and the second electrode is connected to the first auxiliary electrode under the undercut structure.

2. The electroluminescent display device of claim 1, wherein the insulation layer includes a passivation layer and an overcoat layer over the passivation layer,
wherein the contact hole includes a first contact hole provided in the passivation layer and a second contact hole provided in the overcoat layer, and
wherein a length of the second contact hole is greater than a length of the first contact hole, and a width of the second contact hole is smaller than a width of the first contact hole.

3. The electroluminescent display device of claim 2, wherein the first and second contact holes have a cross shape in plan.

4. The electroluminescent display device of claim 2, wherein the first auxiliary electrode includes an auxiliary hole corresponding to the first and second contact holes, and
wherein the auxiliary hole has a smaller area than the first contact hole and is disposed in the first contact hole.

5. The electroluminescent display device of claim 2, wherein the first auxiliary electrode includes an auxiliary hole corresponding to the first and second contact holes, and
wherein the first contact hole has a smaller area than the auxiliary hole and is disposed in the auxiliary hole.

6. The electroluminescent display device of claim 5, wherein the first contact hole has a cross shape in plan.

7. The electroluminescent display device of claim 2, further comprising a buffer layer between the substrate and the first auxiliary electrode,
wherein the buffer layer has a buffer hole corresponding to the first and second contact holes, and
wherein a thickness of the buffer layer is greater than a thickness of the passivation layer and is equal to or smaller than a thickness of the overcoat layer.

8. The electroluminescent display device of claim 7, wherein the first contact hole is spaced apart from the buffer layer, and the second contact hole overlaps the buffer layer.

9. The electroluminescent display device of claim 1, further comprising a second auxiliary electrode provided between the insulation layer and the light-emitting layer and connected to the first auxiliary electrode through the contact hole,
wherein the light-emitting layer is cut off by the undercut structure to thereby expose the second auxiliary electrode, and the second electrode is in contact with the exposed second auxiliary electrode.

10. The electroluminescent display device of claim 2, wherein the sub-pixel further includes a transparent area, and
wherein the overcoat layer is removed in the transparent area.

11. The electroluminescent display device of claim 1, wherein the first auxiliary electrode is connected to a power line.

12. A method of manufacturing an electroluminescent display device, comprising:
forming a first auxiliary electrode over a substrate;
forming a first insulation layer having a first contact hole and a second insulation layer having a second contact hole over the first auxiliary electrode; and
forming a light-emitting diode over the second insulation layer, the light-emitting diode including a first electrode, a light-emitting layer, and a second electrode,
wherein forming the first insulation layer having the first contact hole and the second insulation layer having the second contact hole includes forming an undercut structure where a bottom surface of the second insulation layer is exposed at at least one side of the second contact hole,
wherein each of the first and second contact holes includes a portion extending in a first direction and a portion extending in a second direction, and
wherein the light-emitting layer is cut off by the undercut structure, and the second electrode is connected to the first auxiliary electrode under the undercut structure.

13. The method of claim 13, wherein the first contact hole is formed after forming the second contact hole.

14. The method of claim 13, further comprising forming an auxiliary hole in the first auxiliary electrode corresponding to the first and second contact holes after forming the first contact hole.

15. The method of claim 12, wherein forming the first auxiliary electrode includes forming an auxiliary hole corresponding to the first and second contact holes.

16. The method of claim 12, further comprising forming a buffer layer between the substrate and the first auxiliary electrode and having a buffer hole corresponding to the first and second contact holes.

17. The method of claim 12, further comprising forming a second auxiliary electrode between the second insulation layer and the light-emitting layer and connected to the first auxiliary electrode,
wherein the light-emitting layer is cut off by the undercut structure to thereby expose the second auxiliary electrode, and the second electrode is in contact with the exposed second auxiliary electrode.

18. The method of claim 12, wherein the first auxiliary electrode is connected to a power line.

19. The method of claim 18, wherein the power line is a low potential power line providing a low potential voltage.

20. The method of claim 12, wherein a length of the second contact hole is greater than a length of the first contact hole, and a width of the second contact hole is smaller than a width of the first contact hole.

21. The method of claim 20, wherein the first and second contact holes have a cross shape in plan.
